(19) United States
(12) Patent Application Publication
(10) Pub. No.: US 2012/0260981 A1
(43) Pub. Date: Oct. 18, 2012

(54) PASTE COMPOSITION FOR ELECTRODE, PHOTOVOLTAIC CELL ELEMENT, AND PHOTOVOLTAIC CELL

(75) Inventors: Shuichiro ADACHI, Tsukuba-shi (JP); Masato Yoshida, Tsukuba-shi (JP); Takeshi Nojiri, Tsukuba-shi (JP); Mitsunori Iwamuro, Tsukuba-shi (JP); Keiko Kizawa, Tsukuba-shi (JP); Takuya Aoyagi, Hitachi-shi (JP); Hiroki Yamamoto, Hitachi-shi (JP); Takashi Naito, Hitachi-shi (JP); Takahiko Kato, Hitachi-shi (JP)

(73) Assignee: HITACHI CHEMICAL COMPANY, LTD.

(21) Appl. No.: 13/444,834

(22) Filed: Apr. 11, 2012

Related U.S. Application Data
(60) Provisional application No. 61/475,443, filed on Apr. 14, 2011.

(51) Int. Cl. H01B 1/02; H01L 31/0224

(52) U.S. Cl. 136/256; 252/512; 252/514; 252/513

(57) ABSTRACT

The present invention provides a paste composition for an electrode, the paste composition including phosphorus-tin-containing copper alloy particles, glass particles, a solvent and a resin. The present invention also provides a photovoltaic cell element having an electrode formed from the paste composition, and a photovoltaic cell.

### CROSS-REFERENCE TO RELATED APPLICATION

This application claims priority under 35 USC 119(e) from U.S. Provisional Application No. 61/475,443, the disclosure of which is incorporated by reference herein.

### BACKGROUND OF THE INVENTION

1. Field of the Invention

The present invention relates to a paste composition for an electrode, a photovoltaic cell element and a photovoltaic cell.

2. Background Art

Generally, electrodes are formed on a light-receiving surface and a back surface of a silicon photovoltaic cell. In order to efficiently extract electrical energy that has been converted in a photovoltaic cell from incident light, it is necessary that the electrodes have sufficiently low volume resistivity and form a favorable ohmic contact with a Si substrate. In particular, in the case of an electrode formed on a light-receiving surface, the width of wires tends to be reduced, and the aspect ratio of the electrode tends to be increased in order to suppress the loss in the amount of incidence of sunlight to a minimum.

An electrode for a light-receiving surface of a photovoltaic cell is typically produced by forming a p-type silicon layer by performing texture (asperity) formation on a light-receiving surface of a p-type silicon substrate, and thermally diffusing phosphorus etc. at high temperature; applying a conductive composition onto the p-type silicon layer by screen printing or the like; and sintering the same in the atmosphere at 800° C. to 900° C. The conductive composition for forming a light-receiving surface electrode contains a conductive metal powder, glass particles and various additives.

As the conductive metal powder, a silver powder is typically used. The reasons therefor include that silver particles have a low volume resistivity of 1.6×10⁻⁶ Ω·cm; that silver particles can be sintered via self-reduction under the aforementioned conditions; that silver particles can form a favorable ohmic contact with a silicon substrate; and that a solder material exhibits excellent wettability with respect to electrodes made of silver particles, whereby tab wires, that electrically connect photovoltaic cell elements with each other, are favorably attached during module formation in which photovoltaic cell elements are sealed with a glass substrate or the like.

As described above, a conductive composition containing silver particles exhibits favorable properties as an electrode for photovoltaic cells. Meanwhile, since silver is a noble metal and is expensive itself, and also in view of resource issues, proposals of a paste material to replace a silver-containing conductive composition have been desired. Copper, which is utilized as a semiconductor wiring material, is one of materials viewed as an alternative for silver. Copper is in abundant supply and is low in price, i.e., approximately a hundredth of that of silver. However, since copper is a material that easily oxidizes at a high temperature of 200° C. or higher in the atmosphere, it is difficult to form an electrode according to the processes described above.

In order to eliminate such a drawback of copper, for example, Japanese Patent Application Laid-Open (JP-A) Nos. 2005-314755 and 2004-217952 disclose copper particles that do not oxidize during high-temperature sintering, the copper particles being imparted with oxidation resistance through various techniques.

### SUMMARY OF THE INVENTION

### Technical Problem

However, copper particles such as described above exhibit oxidation resistance at a temperature of up to 300° C., and are mostly oxidized at high temperatures of from 800° C. to 900° C. Therefore, the copper particles still have not been practically utilized in electrodes for photovoltaic cells. Further, there is a problem in that additives or the like, which are added to impart oxidation resistance to copper particles, disturb sintering of the copper particles during sintering and, as a result, electrodes with low resistance, such as those made of silver, cannot be obtained.

As another technique of suppressing oxidization of copper, there is a special process of sintering a conductive composition, in which copper is used as a conductive metal powder, in an atmosphere of nitrogen, etc.

However, this technique requires an environment that is sealed completely with an atmospheric gas such as described above, in order to thoroughly suppress oxidization of copper particles, which is not suitable for mass production of photovoltaic cell elements from a viewpoint of production costs.

Another problem to overcome in applying copper for electrodes for photovoltaic cells is ohmic contact properties of copper with respect to a silicon substrate. Namely, even if an electrode of copper can be formed without oxidation during high-temperature sintering, interdiffusion of copper and silicon may be caused as a result of direct contact of copper with a silicon substrate, and a reactant phase of copper and silicon (Cu₃Si) may be formed at an interface of the electrode and the silicon substrate.

Formation of Cu₃Si may occur within a region of several μm from the interface of the silicon substrate, which may cause cracking on the Si substrate side. Further, Cu₃Si may penetrate through an n-type silicon layer that is formed previously on the silicon substrate, thereby deteriorating semiconductor performances (pn-junction properties) of the photovoltaic cell. In addition, the formed Cu₃Si may lift up an electrode made of copper and inhibit adhesiveness of the electrode with respect to the silicon substrate, thereby reducing the mechanical strength of the electrode.

The present invention was made in view of the problems described above and aims to provide a paste composition for an electrode, which can suppress oxidization of copper during sintering, form an electrode with low resistivity, and form a copper-containing electrode in which formation of a reactant phase of copper and a silicon substrate is suppressed and that has a favorable ohmic contact. The present invention also aims to provide a photovoltaic cell element and a photovoltaic cell having an electrode formed with the paste composition for an electrode.

### Solution to Problem

The inventors have made intensive studies in order to overcome the aforementioned problems and, as a result, completed the present invention. Specifically, the present invention encompasses the following aspects.

A first aspect of the present invention is a paste composition for an electrode containing phosphorus-tin-containing copper alloy particles, glass particles, a solvent and a resin.

The paste composition for an electrode preferably has a phosphorus content in the phosphorus-tin-containing copper alloy particles of from 2 mass % to 15 mass %, and a content of tin in the phosphorus-tin-containing copper alloy particles of from 5 mass % to 30 mass %.

The glass particles preferably have a glass softening point of 650° C. or less and a crystallization initiation temperature of more than 650° C.

The phosphorus-tin-containing copper alloy particles preferably further contain at least one kind of metal atom selected from the group consisting of silver, manganese and cobalt, and more preferably, the content of the metal atom in the phosphorus-tin-containing copper alloy particles is from 0.1 mass % to 10 mass %.

The paste composition for an electrode preferably further contain silver particles, and more preferably, a content of the silver particles in a total content of the phosphorus-tin-containing copper alloy particles and the silver particles, which is defined as 100 mass %, is from 0.1 mass % to 10 mass %.

In the paste composition for an electrode, it is preferred that a total content of the phosphorus-tin-containing copper alloy particles and the silver particles in the paste composition is from 70 mass % to 94 mass %; a content of the glass particles in the paste composition is from 0.1 mass % to 10 mass %; and a total content of the solvent and the resin in the paste composition is from 3 mass % to 29.9 mass %.

A second aspect of the present invention is a photovoltaic cell element including an electrode formed on a silicon substrate, the electrode being formed by sintering the paste composition for an electrode which has been applied to the silicon substrate.

The electrode preferably contains a Cu—Sn alloy phase and a Sn—P—O glass phase, and more preferably, the Sn—P—O glass phase is positioned between the Cu—Sn alloy phase and the silicon substrate.

A third aspect of the present invention is a photovoltaic cell including the photovoltaic cell element, and a tab wire that is positioned on the electrode of the photovoltaic cell element.

### Effects of the Invention

According to the present invention, it is possible to provide a paste composition for an electrode, which can suppress oxidization of copper during sintering, form an electrode with low resistivity, and form a copper-containing electrode in which formation of a reactant phase between copper and the silicon substrate is suppressed and that has a favorable ohmic contact. It is also possible to provide a photovoltaic cell element, and a photovoltaic cell having an electrode formed from the paste composition for an electrode.

### BRIEF DESCRIPTION OF THE DRAWINGS

Exemplary embodiments of the present invention will be described in detail based on the following drawings, wherein:

FIG. 1 is a schematic cross-sectional view showing an example of a silicon photovoltaic cell element according to the present invention;

FIG. 2 is a schematic plan view showing an example of a light-receiving surface of a silicon photovoltaic cell element according to the present invention;

FIG. 3 is a schematic plan view showing an example of a back surface of a silicon photovoltaic cell element according to the present invention;

FIG. 4 is a schematic plan view showing an example of a structure of a back surface-side electrode of a back-contact type photovoltaic cell element according to the present invention;

FIG. 5 is a schematic perspective view showing an example of an AA cross-section constitution a back-contact type photovoltaic cell element according to the present invention shown in FIG. 4;

FIG. 6 is a schematic perspective view showing an example of an AA cross-section constitution of a back-contact type photovoltaic cell element according to the present invention shown in FIG. 4; and

FIG. 7 is a schematic perspective view showing an example of an AA cross-section constitution of a back-contact type photovoltaic cell element according to the present invention shown in FIG. 4.

### DETAILED DESCRIPTION OF THE INVENTION

In the present specification, the term “process” refers not only to an independent process but also to a process that cannot be clearly distinguished from another process, insofar as an intended result of the process can be attained. Further, a numerical range expressed by “A to B” refers to a range including A and B as the minimum value and the maximum value, respectively.

With regard to the amount of components of a composition, when plural substances corresponding to the same component exist in the composition, the amount of the component refers to the total amount of the plural substances, unless otherwise specified.

[Paste Composition for Electrode]

The paste composition for an electrode according to the present invention contains at least one kind of phosphorus-tin-containing copper alloy particles, at least one kind of glass particles, at least one kind of a solvent, and at least one kind of a resin. By using a paste composition having a constitution as described above, oxidation of copper during sintering in the atmosphere can be suppressed and an electrode with low resistivity can be formed. Further, formation of a reactant phase of copper and a silicon substrate can be suppressed and a favorable ohmic contact between a formed electrode and the silicon substrate can be obtained.

(Phosphorus-Tin-Containing Copper Alloy Particles)

The paste composition for an electrode contains at least one kind of phosphorus-tin-containing copper alloy particles. As a phosphorus-containing copper alloy, a brazing material referred to as a copper-phosphorus brazing alloy (phosphorus concentration: approximately 7 mass % or less) is known. Although a copper-phosphorus brazing alloy is used also as a jointing material of copper and copper, by using phosphorus-containing copper alloy particles in the paste composition for an electrode according to the present invention, an electrode that exhibits excellent oxidation resistance and a low volume resistivity can be formed, by means of a reducing property of phosphorus with respect to oxidized copper. Furthermore, effects of enabling sintering an electrode at low temperature, thereby reducing processing costs, can be achieved.

The phosphorus-tin-containing copper alloy particles used in the present invention are particles composed of a copper alloy containing phosphorus and tin. By including tin in copper alloy particles, an electrode that exhibits low resistivity and superior adhesion can be formed during a sintering process as described later.

This is considered, for example, that if copper alloy particles contain phosphorus and tin, phosphorus, tin and copper react one another in a sintering process, and an electrode composed of a Cu—Sn alloy phase and a Sn—P—O glass phase. It is believed that the Cu—Sn alloy phase forms a compact bulk in the electrode, and since it functions as a conductive layer, an electrode with low resistivity can be formed.

In the present specification, the compact bulk refers to a structure in which Cu—Sn alloy phases in massive form closely contact each other in a three-dimensional continuous manner.

The compact bulk refers to a structure in which Cu—Sn alloy phases in massive form closely contact each other in a three-dimensional continuous manner.

Further, in cases in which an electrode is formed with the paste composition for an electrode according to the present invention on a substrate containing silicon (hereinafter also referred to “silicon substrate”), an electrode that exhibits high adhesion with respect to the silicon substrate can be formed, and a favorable ohmic contact between the electrode and the silicon substrate can be achieved.

It is considered, for example, that phosphorus and tin contained in copper alloy particles react with each other in a sintering process, whereby an electrode composed of a Cu—Sn alloy phase and a Sn—P—O glass phase is formed. Since the Cu—Sn alloy phase is a compact bulk, the Sn—P—O glass phase is formed between the Cu—Sn alloy phase and the silicon substrate. As a result, it is believed that adhesion of the Cu—Sn alloy phase with respect to the silicon substrate is improved. Further, since the Sn—P—O glass phase functions as a barrier layer that inhibits interdiffusion of copper and silicon, it is believed that a favorable ohmic contact between an electrode formed by sintering and a silicon substrate can be achieved. More specifically, it is considered that a favorable ohmic contact can be obtained while suppressing formation of a reactant phase (Cu₃Si), which is formed when an electrode containing copper is contacted directly with silicon and heated, and maintaining adhesion with respect to the silicon substrate without deteriorating the semiconductor performances (e.g. pn-junction properties).

Such effects are generally expressed in cases in which an electrode is formed on a substrate containing silicon with a paste composition for an electrode according to the present invention, and there is no particular restriction on the type of the substrate containing silicon. Examples of the substrate containing silicon include silicon substrates for photovoltaic cells and silicon substrates for other semiconductor devices than photovoltaic cells.

Specifically, according to the present invention, in which phosphorus-tin-containing copper alloy particles are included in the paste composition for an electrode, an electrode that exhibits a low volume resistivity and excellent oxidation resistance can be formed by utilizing the reducing property of phosphorus atoms with respect to oxidized copper in the phosphorus-tin-containing copper alloy particles. Next, through reaction between the phosphorus-tin-containing copper alloy particles, a conductive layer composed of a Cu—Sn alloy phase, and an Sn—P—O glass phase, are formed while maintaining the low volume resistivity. It is thus considered, for example, that the two characteristic mechanisms can be attained during sintering by the Sn—P—O glass phase that functions as a barrier layer that prevents interdiffusion of copper and silicon, i.e., suppressed formation of a reactant phase between the electrode and the silicon substrate, and formation of a favorable ohmic contact with a copper electrode.

The content of phosphorus in the phosphorus-tin-containing copper alloy in the present invention is not particularly restricted. From the viewpoints of oxidation resistance and low resistivity, the phosphorus content is preferably from 2 mass % to 15 mass % or less, more preferably from 3 mass % to 12 mass %, and further preferably from 4 mass % to 10 mass %. If the phosphorus content in the phosphorus-tin-containing copper alloy is 15 mass % or less, lower resistivity can be attained, and the productivity of phosphorus-tin-containing copper alloy particles can be superior. If the phosphorus content is 2 mass % or more, even more favorable oxidation resistance can be attained.

The content of tin in the phosphorus-tin-containing copper alloy is not particularly restricted. From the viewpoints of oxidation resistance and reactivity with copper and phosphorus, the tin content is preferably from 5 mass % to 30 mass %, more preferably from 6 mass % to 25 mass %, and further preferably from 7 mass % to 20 mass %. If the tin content in the phosphorus-tin-containing copper alloy is 30 mass % or less, a sufficient volume of Cu—Sn alloy phase can be formed, and the volume resistivity of an electrode can be decreased. If the tin content is 5 mass % or more, reaction with copper and phosphorus can be caused more uniformly.

From the viewpoints of oxidation resistance, low resistance, and reactivity with copper and phosphorus, the combination of the phosphorus content and the tin content in the phosphorus-tin-containing copper alloy is preferably that the phosphorus content is from 2 mass % to 15 mass % and the tin content is from 5 mass % to 30 mass % or less, more preferably the phosphorus content is from 3 mass % to 12 mass % and the tin content is from 6 mass % to 25 mass %, and further preferably the phosphorus content is from 4 mass % to 10 mass % and the tin content is from 7 mass % to 20 mass %.

A copper alloy containing at least one kind of metal atoms selected from the group consisting of silver, manganese and cobalt, in addition to phosphorus and tin, is also a suitable example of the phosphorus-tin-containing copper alloy used in the present invention. By containing additional metal atoms, an electrode with lower resistance can be formed.

The content of other metal atoms in the copper alloy containing phosphorus, tin and other metal atoms may be selected appropriately according to the type of the other metal atoms, intended applications, or the like. For example, the content of other metal atoms may be from 0.05 mass % to 20 mass %, preferably from 0.1 mass % to 15 mass %, and more preferably from 1 mass % to 10 mass %. If the content of the other metal atoms is 0.05 mass % or more, the melting point of alloy particles can be further lowered, and sintering reaction of alloy particles during a sintering process can be promoted. If the content of the other metal atoms is 20 mass % or less, oxidation resistance is improved and an electrode with low resistance can be formed.

The phosphorus-tin-containing particles may further contain other atoms. Examples of the other atoms include Sb, Si, K, Na, Li, Ba, Li, Sr, Ca, Mg, Be, Zn, Pb, Cd, Tl, V, Al, Zr, W, Mo, Ti, Ni and Au.

The content of other atoms in the phosphorus-tin-containing alloy particles may be, for example, 3 mass % or less. From the viewpoints of oxidation resistance and low resistivity, it is preferably 1 mass % or less.

In the present invention, the phosphorus-tin-containing alloy particles may be used singly or in a combination of two or more kinds.

The particle size of the phosphorus-tin-containing alloy particles is not particularly restricted, but the particle size at an accumulated weight of 50% (hereinafter, also abbreviated as “D50%”) is preferably from 0.4 μm to 10 μm, and more preferably from 1 μm to 7 μm. If the particle size is 0.4 μm or more, oxidation resistance can be improved more efficiently. If the particle size is 10 μm or less, the contact area among phosphorus-tin-containing copper alloy particles in an electrode can be increased, whereby resistivity can be lowered more efficiently. The particle size of phosphorus-tin-containing copper alloy particles can be measured with a particle size distribution analyzer (MICROTRAC MT3300, trade name, manufactured by Nikkiso Co., Ltd.).

The shape of the phosphorus-tin-containing copper alloy particles is not particularly restricted, and it may be any of quasispherical, flat, blocky, platy, scaly, etc. From the viewpoints of oxidation resistance and low resistivity, the phosphorus-tin-containing copper alloy particles preferably have a quasispherical, flat or platy shape.

The content of the phosphorus-tin-containing copper alloy particles in the paste composition for an electrode is not particularly restricted. From the viewpoints of oxidation resistance and low resistivity, the content in the paste composition for an electrode is preferably from 70 mass % to 94 mass %, more preferably from 74 mass % to 88 mass %.

Phosphorus-tin-containing copper alloys can be produced by an ordinary method. Phosphorus-tin-containing copper alloy particles can be produced from a phosphorus-tin-containing copper alloy, in which the amount of phosphorus and tin has been adjusted, by an ordinary method of preparing a metal powder, such as a water atomization method. Details of the water atomization method may be referred to descriptions in Kinzoku Binran (Metals Handbook, published by Maruzen Co., Ltd.), etc.

More specifically, desired phosphorus-tin-containing copper alloy particles can be produced by melting a phosphorus-tin-containing copper alloy and making the same into a powder by spraying from nozzles, and then drying and classifying the obtained powder. Further, phosphorus-tin-containing alloy particles having a desired particle diameter can be produced by appropriately selecting the conditions for classification.

(Glass Particles)

The paste composition for an electrode according to the present invention contains at least one kind of glass particles. If the paste composition for an electrode contains glass particles, adhesion between an electrode portion and a substrate is improved during sintering. Further, especially in the formation of an electrode on a light-receiving surface side of a photovoltaic cell, a silicon nitride film, which is an antireflection coating, is removed by so called fire-through during sintering, and an ohmic contact between an electrode and a silicon substrate is obtained.

From the viewpoints of adhesion with respect to a substrate and reduction in resistivity, the glass particles preferably contain glass having a glass softening point of 650° C. or less and a crystallization initiation temperature of higher than 650° C.

The glass softening point is measured by an ordinary method with a thermal mechanical analyzer (TMA), and the crystallization initiation temperature is measured by an ordinary method with a thermogravimetric-differential thermal analyzer (TG-DTA).

In the event that the paste composition for an electrode according to the present invention is used for an electrode formed on the light-receiving surface side of a photovoltaic cell, glass particles that are used commonly in the art can be used without particular restriction, as long as that can remove an antireflection coating by softening or melting at an electrode forming temperature, oxidizing the silicon nitride film to which the glass particles contact, and taking in the oxidized silicon dioxide.

Typically, glass particles to be contained in a paste composition for an electrode are composed of glass containing lead, since the material can efficiently take in silicon dioxide. Examples of glass containing lead include those described in Japanese Patent No. 3050064, which can be suitably used in the present invention.

Considering environmental impact, lead-free glass, which does not substantially contain lead, is preferably used in the present invention. Examples of the lead-free glass include those described in paragraphs [0024] to [0025] of Japanese Patent Application Laid-Open No. 2006-313744, and those described in Japanese Patent Application Laid-Open No. 2009-188281, and any one of such lead-free glass may be selected appropriately and used in the present invention.

If the paste composition for an electrode according to the present invention is used for an electrode other than that formed on a light-receiving surface side of a photovoltaic cell, for example, for a back-surface output electrode, or a through-hole electrode or a back-surface electrode of a back-contact type photovoltaic cell element, inclusion of a material that is necessary for fire through, such as lead, can be omitted by using glass particles containing glass having a glass softening point of 650° C. or less, and a crystallization initiation temperature of higher than 650° C.

Examples of the glass component of the glass particles to be used in the paste composition for an electrode according to the present invention include silicon dioxide (SiO₂), phosphorus oxide (P₂O₅), aluminum oxide (Al₂O₃), boron oxide (B₂O₃), vanadium oxide (V₂O₅), potassium oxide (K₂O), bismuth oxide (Bi₂O₃), sodium oxide (Na₂O), lithium oxide (Li₂O), barium oxide (BaO), strontium oxide (SrO), calcium oxide (CaO), magnesium oxide (MgO), beryllium oxide (BeO), zinc oxide (ZnO), lead oxide (PbO), cadmium oxide (CdO), tin oxide (SnO), zirconium oxide (ZrO₂), tungsten oxide (WO₃), molybdenum oxide (MoO₃), lanthanum oxide (La₂O₃), niobium oxide (Nb₂O₅), tantalum oxide (Ta₂O₅), yttrium oxide (Y₂O₃), titanium oxide (TiO₂), germanium oxide (GeO₂), tellurium oxide (TeO₂), lutetium oxide (Lu₂O₃), antimony oxide (Sb₂O₃), copper oxide (CuO), iron oxide (FeO), silver oxide (AgO) and manganese oxide (MnO).

Among these, at least one kind selected from the group consisting of SiO₂, P₂O₅, Al₂O₃, B₂O₃, V₂O₅, Bi₂O₃, ZnO and PbO is preferably used as the glass component, and at least one kind selected from the group consisting of SiO₂, PbO, B₂O₃, Bi₂O₃ and Al₂O₃ is more preferred. These glass particles can effectively lower the softening point. Further, since wettability with respect to phosphorus-tin-containing copper alloy particles, or silver particles that are optionally included, can be improved, sintering among the particles in the sintering process is promoted and an electrode with even lower resistivity can be formed.

Meanwhile, from the viewpoint of low contact resistivity, glass particles containing phosphorus pentoxide (phosphate glass, P₂O₅ glass particles) are preferable, and glass particles containing vanadium pentoxide and phosphorus pentoxide (P₂O₅-V₂O₅ glass particles) are more preferable. By containing vanadium pentoxide, oxidation resistance is further improved and resistivity of an electrode is further lowered. This is considered to be because of reduction in the softening point of the glass as a result of further containing, for example, vanadium pentoxide. If glass particles containing phosphorus pentoxide and vanadium pentoxide (P₂O₅-V₂O₅ glass particles) are used, the content of vanadium pentoxide in the total mass of the glass is preferably 1 mass % or more, and more preferably from 1 mass % to 70 mass %.

Although the particle size of the glass particles used in the present invention is not particularly restricted, the particle size at an accumulated weight of 50% (D50%) is preferably from 0.5 μm to 10 μm, more preferably from 0.8 μm to 8 μm, further preferably from 1 μm to 5 μm.

If the particle size is 0.5 μm or more, workability in producing the paste composition for an electrode can be improved. If the particle size is 10 μm or less, the particles can be dispersed homogeneously in the paste composition for an electrode. As a result, fire-through can be efficiently caused in a sintering process, and adhesion with respect to a silicon substrate can be improved. The particle size of phosphorus-tin-containing copper alloy particles can be measured with a particle size distribution analyzer (MICROTRAC MT3300, trade name, manufactured by Nikkiso Co., Ltd.).

The shape of the glass particles is not particularly restricted, and may be any of quasispherical, flat, blocky, platy, scaly, etc. From the viewpoints of oxidation resistance and low resistivity, the glass particles preferably have a quasispherical, flat, or platy shape.

The content of the glass particles in the total mass of the paste composition for an electrode is preferably from 0.1 mass % to 10 mass %, more preferably from 0.5 mass % to 8 mass %, and further preferably from 1 mass % to 8 mass %. If the content of the glass particles is within the range, oxidation resistance, reduction in resistivity of an electrode, and reduction in contact resistance can be attained more effectively, and reaction of phosphorus, tin and copper contained in the phosphorus-containing copper alloy particles can be promoted.

(Solvent and Resin)

The paste composition for an electrode according to the present invention contains at least one kind of solvent and at least one kind of resin. By including a solvent and a resin, liquid properties (such as viscosity or surface tension) of the paste composition for an electrode according to the present invention can be adjusted to suitable liquid properties according to a method of applying the paste composition to a silicon substrate, etc.

The solvent is not particularly restricted, and examples thereof include a hydrocarbon solvent, such as hexane, cyclohexane, and toluene; a chlorinated hydrocarbon solvent, such as dichloroethylene, dichloroethane, and dichlorobenzene; a cyclic ether solvent, such as tetrahydrofuran, furan, tetrahydropyran, pyran, dioxane, 1,3-dioxolane, and trioxane; an amide solvent, such as N,N-dimethylformamide, and N,N-dimethylacetamide; a sulfoxide solvent, such as dimethylsulfoxide, and diethylsulfoxide; a ketone solvent, such as acetone, methyl ethyl ketone, diethylketone, and cyclohexanone; an alcohol compound, such as ethanol, 2-propanol, 1-butanol, and diacetone alcohol; a polyhydric alcohol ester solvent, such as 2,2,4-trimethyl-1,3-pentanediol monoacetate, 2,2,4-trimethyl-1,3-pentanediol monopropiolate, 2,2,4-trimethyl-1,3-pentanediol monobutyrate, 2,2,4-trimethyl-1,3-pentanediol monoisobutyrate, 2,2,4-triethyl-1,3-pentanediol monoacetate, ethylene glycol monobutyl ether acetate, and diethylene glycol monobutyl ether acetate; a polyhydric alcohol ether solvent, such as butyl cellosolve, diethylene glycol monobutyl ether, and diethylene glycol diethyl ether; a terpene solvent, such as α-terpinene, α-terpineol, myrcene, allo-ocimene, limonene, dipentene, α-pinene, β-pinene, terpineol, carvone, ocimene, and phellandrene, and mixtures of these solvents.

From the viewpoint of coating properties and printing properties of the paste composition for an electrode according to the present invention, when it is applied to a silicon substrate, the solvent is preferably at least one selected from a polyhydric alcohol ester solvent, a terpene solvent, and a polyhydric alcohol ether solvent, and at least one selected from a polyhydric alcohol ester solvent and a terpene solvent is more preferable.

According to the present invention, the solvents may be used singly or in a combination of two or more kinds.

A resin used commonly in the art can be used without particular restriction, insofar as it can be thermally decomposed during sintering. Specific examples of the resin include a cellulosic resin, such as methylcellulose, ethylcellulose, carboxymethylcellulose, and nitrocellulose; polyvinyl alcohols; polyvinylpyrrolidones; an acrylic resin; a vinyl acetate/acrylic ester copolymer; a butyral resin such as polyvinyl butyral; an alkyd resin, such as a phenol modified alkyd resin, and a castor oil fatty acid modified alkyd resin; an epoxy resin; a phenol resin; and a rosin ester resin.

From the viewpoint of a property of disappearance during sintering, at least one selected from a cellulosic resin or an acrylic resin is preferable as the resin used in the present invention.

In the present invention, the resin may be used singly or in a combination of two or more kinds.

The weight-average molecular weight of the resin according to the present invention is not particularly restricted. The weight-average molecular weight is preferably from 5,000 to 500,000, and more preferably from 10,000 to 300,000. If the weight-average molecular weight of the resin is 5,000 or more, increase in viscosity of the paste composition for an electrode can be suppressed. The increase in viscosity is considered to be, for example, caused by aggregation of particles due to insufficient steric repulsion when the resin is adsorbed to phosphorus-in-containing copper alloy particles. If the weight-average molecular weight of the resin is 500,000 or less, aggregation of the resin in a solvent is suppressed, and increase in viscosity of the paste composition for an electrode can be suppressed.

In addition, if the weight-average molecular weight of the resin is 500,000 or less, increase in a combustion temperature of the resin can be suppressed. As a result, when the paste composition for an electrode is subjected to sintering, remaining of the resin as a foreign material due to incomplete combustion can be suppressed, and an electrode having even lower resistivity can be obtained.

The contents of the solvent and the resin in the paste composition for an electrode according to the present invention can be selected appropriately, depending on the desired liquid properties and the type of the solvent and the resin. For example, the total content of the solvent and the resin in the total mass of the paste composition for an electrode is preferably from 3 mass % to 29.9 mass %, more preferably from 5 mass % to 25 mass %, and further preferably from 7 mass % to 20 mass %.

If the total content of the solvent and the resin is within the range, application suitability of the paste composition for an electrode to a silicon substrate may become favorable, and an electrode having a desired width and a height can be formed easier.

Further, in the paste composition for an electrode according to the present invention, from the viewpoints of oxidation resistance and low resistivity of an electrode, it is preferred that the total content of the phosphorus-tin-containing copper alloy particles is from 70 mass % to 94 mass %, the content of the glass particles is from 0.1 mass % to 10 mass %, and the total content of the solvent and the resin is from 3 mass % to 29.9 mass %; it is more preferred that the total content of the phosphorus-tin-containing copper alloy particles is from 74 mass % to 88 mass %, the content of the glass particles is from 0.5 mass % to 8 mass %, and the total content of the solvent and the resin is from 7 mass % to 20 mass %; and it is further preferred that the total content of the phosphorus-tin-containing copper alloy particles is from 74 mass % to 88 mass %, the content of the glass particles is from 1 mass % to 8 mass %, and the total content of the solvent and the resin is from 7 mass % to 20 mass %.

(Silver Particles)

The paste composition for an electrode according to the present invention preferably further includes silver particles. By including silver particles, oxidation resistance can be further improved and resistivity of an electrode can be further lowered. In addition, separation of Ag particles in an Sn—P—O glass phase, which is formed by reaction of the phosphorus-tin-containing copper alloy particles, further improves the ohmic contact between a Cu—Sn alloy phase in an electrode layer and a silicon substrate. Moreover, when a photovoltaic cell module is formed, an effect of improving the solder jointing property can be obtained.

The silver that constitutes the silver particles may further contain other atoms that may be unavoidably incorporated therein. Examples of the other atoms include Sb, Si, K, Na, Li, Ba, Sr, Ca, Mg, Be, Zn, Pb, Cd, Tl, V, Sn, Al, Zr, W, Mo, Ti, Co, Ni, and Au.

The content of the other atoms in the silver particles may be, for example, 3 mass % or less of the silver particles, and from the viewpoints of the melting point and reduction in resistivity of an electrode, the content of the other atoms is preferably 1 mass % or less.

Although the particle size of the silver particles used in the present invention is not particularly restricted, the particle size at an accumulated weight of 50% (D50%) is preferably from 0.4 μm to 10 μm, and more preferably from 1 μm to 7 μm. If the particle size is 0.4 μm or more, oxidation resistance is improved more effectively. If the particle size is 10 μm or less, the contact area between the silver particles and the phosphorus-tin-containing copper alloy particles, in an electrode, can be increased, and the resistivity can be lowered more effectively.

The shape of the silver particles is not particularly restricted, and may be any of quasispherical, flat, blocky, platy, scaly, etc. From the viewpoints of oxidation resistance and low resistivity, the silver particles preferably have a quasispherical, flat, or platy shape.

Further, in the event that the paste composition for an electrode according to the present invention contains silver particles, the content of the silver particles is preferably from 0.1 mass % to 10 mass %, more preferably from 0.5 mass % to 8 mass %, when the total content of the phosphorus-tin-containing copper alloy particles and the silver particles, is defined as 100 mass %.

In the paste composition for an electrode according to the present invention, from the viewpoints of oxidation resistance, reduction in resistivity of an electrode, and application suitability to a silicon substrate, the total content of the phosphorus-tin-containing copper alloy particles and the silver particles in the paste composition for an electrode is preferably from 70 mass % to 94 mass %, and more preferably from 74 mass % to 88 mass %. If the total content of the phosphorus-tin-containing copper alloy particles and the silver particles is 70 mass % or more, a favorable viscosity for application of the paste composition for an electrode can be obtained easily. If the total content of the phosphorus-tin-containing copper alloy particles and the silver particles is 94 mass % or less, unevenness during application of the paste composition for an electrode can be more effectively suppressed.

If the paste composition for an electrode according to the present invention further contains silver particles, from the viewpoints of oxidation resistance and low resistivity of an electrode, it is preferred that the total content of the phosphorus-tin-containing copper alloy particles and the silver particles is from 70 mass % to 94 mass %, the content of the glass particles is from 0.1 mass % to 10 mass %, and the total content of the solvent and the resin is from 3 mass % to 29.9 mass %; it is more preferred that the total content of the phosphorus-tin-containing copper alloy particles and the silver particles is from 74 mass % to 88 mass %, the content of the glass particles is from 0.5 mass % to 8 mass %, and the total content of the solvent and the resin is from 7 mass % to 20 mass %; and it is further preferred that the total content of the phosphorus-tin-containing copper alloy particles and the silver particles is from 74 mass % to 88 mass %, the content of the glass particles is from 1 mass % to 8 mass %, and the total content of the solvent and the resin is from 7 mass % to 20 mass %.

(Flux)

The paste composition for an electrode may further include at least one kind of flux. By including a flux, an oxidized film, which is formed on surfaces of phosphorus-tin-containing copper alloy particles, can be removed and a reducing reaction of phosphorus-tin-containing copper alloy particles during sintering can be promoted. Further, melting of the phosphorus-tin-containing copper alloy particles during sintering is also promoted, whereby reaction with the phosphorus-tin-containing copper alloy particles is promoted. As a result, oxidation resistance can be further improved and resistivity of an electrode to be formed can be further lowered. Moreover, an effect of enhancing the adhesion between an electrode material and a silicon substrate can be obtained.

The flux used in the present invention is not particularly restricted, insofar as it is capable of removing an oxidized film formed on surfaces of phosphorus-tin-containing copper alloy particles, and promoting melting of the phosphorus-tin-containing copper alloy particles. Preferred examples of the flux include a fatty acid, a boric acid compound, a fluoride compound, and a fluoroborate compound.

More specifically, examples of the flux include lauric acid, myristic acid, palmitic acid, stearic acid, sorbic acid, stearolic acid, propionic acid, boron oxide, potassium borate, sodium borate, lithium borate, potassium fluoroborate, sodium fluoroborate, lithium fluoroborate, potassium bifluoride, sodium bifluoride, lithium bifluoride, potassium fluoride, sodium fluoride, and lithium fluoride.

Among them, from the viewpoints of heat resistance during a process of sintering an electrode material (i.e., a property of not volatilizing at a low temperature stage of sintering) and supplementary oxidation resistance for phosphorus-tin-containing copper alloy particles, examples of the especially preferred flux include potassium borate and potassium fluoroborate.

According to the present invention, the flux may be used singly or in a combination of two or more kinds.

In the event that the paste composition for an electrode according to the present invention contains a flux, from the viewpoints of allowing the phosphorus-tin-containing copper alloy particles to effectively exhibit oxidation resistance and promoting melting of the phosphorus-tin-containing copper alloy particles, and also from the viewpoint of lowering the porosity at a portion at which the flux is removed after the completion of sintering an electrode material, the content of the flux in the total mass of the paste composition for an electrode is preferably from 0.1 mass % to 5 mass %, more preferably from 0.3 mass % to 4 mass %, further preferably from 0.5 mass % to 3.5 mass %, yet further preferably from 0.7 to 3 mass %, and particularly preferably from 1 mass % to 2.5 mass %.

(Other Components)

The paste composition for an electrode according to the present invention may include other components that are commonly used in the art, in addition to the components as described above, as necessary. Examples of the other components include a plasticizer, a dispersant, a surfactant, an inorganic binder, a metal oxide, a ceramic, and an organometallic compound.

The method for producing the paste composition for an electrode according to the present invention is not particularly restricted. For example, the paste composition for an electrode according to the present invention can be produced by dispersing/mixing phosphorus-tin-containing copper alloy particles, glass particles, solvent and resin, and optionally silver particles, etc., with an ordinary dispersing/mixing method.

The dispersing/mixing method is not particularly restricted, and may be selected from ordinary dispersing/mixing methods.

From the viewpoints of application suitability, the paste composition for an electrode preferably contains phosphorus-tin-containing copper alloy particles, glass particles, a solvent and a resin, and has a viscosity at 25° C. of from 20 Pa·s to 1000 Pa·s, more preferably from 25 Pa·s to 800 Pa·s, and further preferably from 30 Pa·s to 600 Pa·s.

The viscosity of the paste composition for an electrode is measured with a Brookfield HBT viscometer at 25° C.

Further, the paste composition for an electrode preferably contains phosphorus-tin-containing copper alloy particles, glass particles, a solvent and a resin, and has a solid content concentration of from 70 mass % to 98 mass %, more preferably from 75 mass % to 96 mass %, further preferably from 80 mass % to 95 mass %.

The solid content concentration of the paste composition for an electrode refers to the balance obtained by subtracting volatile components from the total components of the paste composition for an electrode. Specifically, the solid content concentration is calculated based on the result obtained after removing volatile components by allowing the paste composition for an electrode to stand for 10 hours under the conditions of 25° C. and 1 atm.

(Method for Producing Electrode with Paste Composition for Electrode)

In the method for producing an electrode with the paste composition for an electrode according to the present invention, an electrode can be formed at a desired portion by applying the paste composition for an electrode to a portion at which an electrode is to be formed, and drying and sintering the paste composition for an electrode. By using the paste composition for an electrode, an electrode with low resistivity can be formed even if a sintering treatment is carried out in the presence of oxygen (e.g. in the atmosphere).

Specifically, for example, in the event that an electrode for a photovoltaic cell is formed with the paste composition for an electrode, the paste composition for an electrode is applied to a silicon substrate in a desired shape, dried and sintered, whereby an electrode for a photovoltaic cell with low resistivity can be formed in a desired shape. By using the paste composition for an electrode, an electrode with low resistivity can be formed even if a sintering treatment is carried out in the presence of oxygen (e.g. in the atmosphere). Further, when an electrode is formed on a silicon substrate, the electrode exhibits excellent adhesion with respect to the silicon substrate and a favorable ohmic contact can be attained.

Examples of the application method of the paste composition for an electrode include a screen printing method, an inkjet method and a dispenser method. From the viewpoint of productivity, a screen printing method is preferable.

If the paste composition for an electrode according to the present invention is applied by screen printing, the paste composition for an electrode preferably has a viscosity in a range of from 20 Pa·s to 1000 Pa·s. The viscosity of the paste composition for an electrode is measured with a Brookfield HBT viscometer at 25° C.

The application amount of the paste composition for an electrode can be selected appropriately, according to the size of an electrode to be formed. The application amount of the paste composition for an electrode may be, for example, from 2 g/m² and 10 g/m², and preferably from 4 g/m² and 8 g/m².

With regard to the conditions for heat treatment (sintering) for forming an electrode with the paste composition for an electrode according to the present invention, heat treatment conditions that are common in the art may be employed.

Although the heat treatment temperature (sintering temperature) is typically from 800° C. to 900° C., in the event where the paste composition for an electrode according to the present invention is used, heat treatment conditions at lower temperatures may be applied. For example, an electrode that exhibits favorable properties can be formed at a heat treatment temperature of from 450° C. to 850° C.

Further, the heat treatment time may be selected appropriately according to the heat treatment temperature, etc., and may be, for example, from 1 second to 20 seconds.

The heat treatment equipment may be appropriately selected from those that can heat up to a temperature within the range as described above, and examples thereof include an infrared heating oven and a tunnel oven. An infrared heating oven, in which electrical energy is input directly to a heated material in the form of electromagnetic waves and is converted to thermal energy, is high in efficiency and capable for performing rapid heating in a short time. Further, since no combustion product is generated and heating is carried out in a non-contact manner, contamination of an electrode to be formed can be prevented. A tunnel oven, in which sintering is carried out during conveying a sample in an automatic and continuous manner from an inlet to an outlet, is capable of carrying out heating uniformly by dividing the oven and controlling the conveying speed. From the viewpoint of photovoltaic performances of a photovoltaic cell element, a tunnel oven is suitable for carrying out the heat treatment.

The volume resistivity of the electrode is not particularly restricted. From the viewpoint of photovoltaic performance of a photovoltaic cell element, the volume resistivity is preferably from 1×10⁻⁴ Ω·cm or less, more preferably 8×10⁻⁵ Ω·cm or less, further preferably 6×10⁻⁶ Ω·cm or less.

The volume resistivity of an electrode can be measured by preparing a sintered body, which is obtained by applying the paste composition for an electrode to an appropriate substrate, and sintering the same, and measuring the volume resistivity of the sintered body with a 4-pin probe resistivity meter (LORESTA-EP MCP-T360, trade name, manufactured by Mitsubishi Chemical Analytech Co., Ltd.)

[Photovoltaic Cell Element and Method for Producing the Same]

A photovoltaic cell element according to the present invention includes an electrode formed by sintering the paste composition for an electrode that has been applied onto a silicon substrate. As the result, a photovoltaic cell element that exhibits favorable characteristics can be obtained, and superior productivity of the photovoltaic cell element can be achieved.

In the present specification, the term “photovoltaic cell element” refers to an element including a silicon substrate having a pn-junction formed thereon, and an electrode formed on the silicon substrate. The term “photovoltaic cell” refers to an assembly that includes an electrode for a photovoltaic cell element having a tab wire provided thereon, which may be plural photovoltaic cell elements that are connected to each other via tab wires, and is sealed with a sealing resin or the like.

In the following, specific examples of the photovoltaic cell element according to the present invention will be described with reference to the drawings. However, the present invention is not limited thereto.

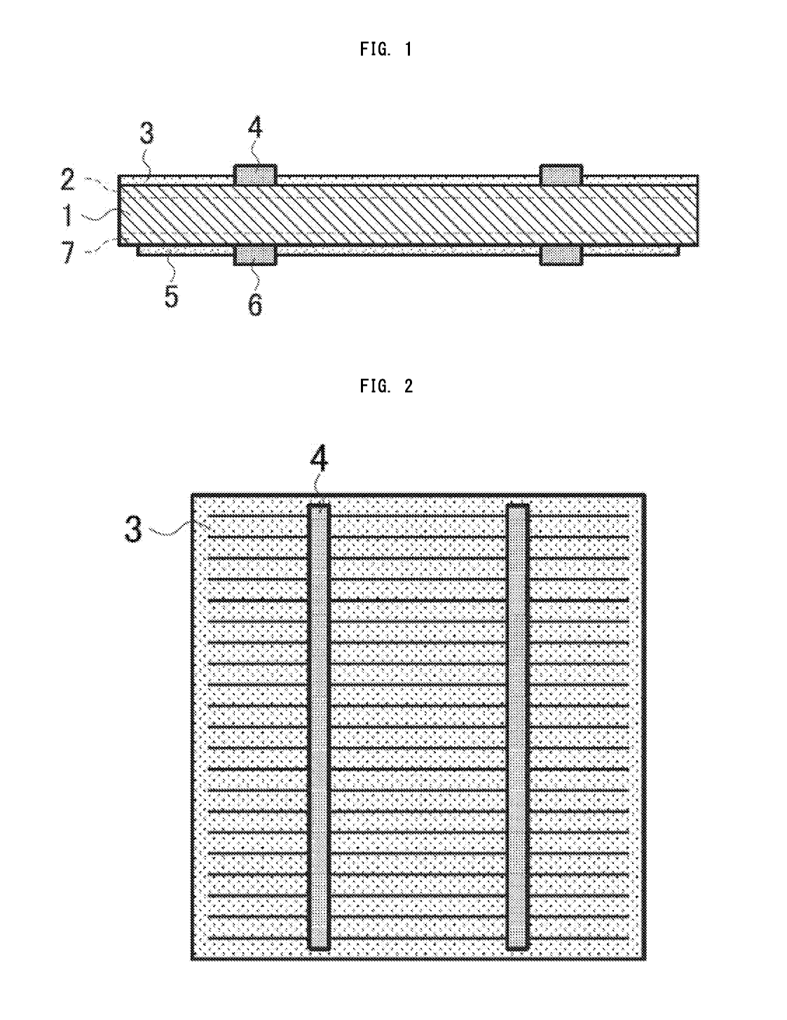

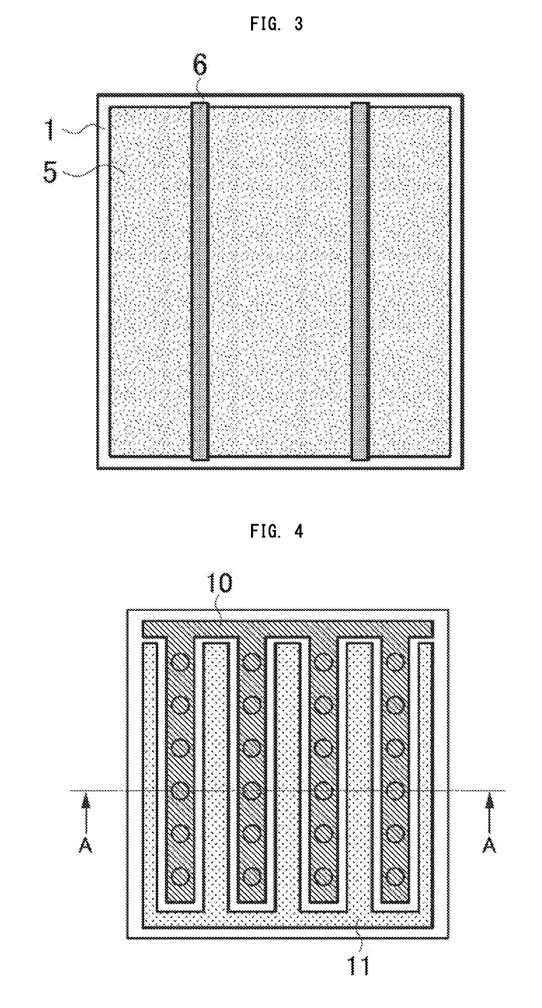

FIG. 1, FIG. 2 and FIG. 3 show schematic views of a cross section, a light-receiving surface and a back surface of an example of a typical photovoltaic cell element.

As outlined in FIG. 1, monocrystalline or polycrystalline silicon, or the like is typically used for a semiconductor substrate 1 of a photovoltaic cell element. The semiconductor substrate 1 contains boron, etc. and constitutes a p-type semiconductor. In order to suppress reflection, the light-receiving surface side is roughened to form asperity (also referred to as “texture”, not illustrated) with an etching solution composed of NaOH and IPA (isopropyl alcohol). The light-receiving surface side is doped with phosphorus or the like to form an n⁺ diffusion layer 2 with a thickness of a sub-micron scale, and a pn-junction region is formed at a boundary with a p-type bulk portion. Further, on the light-receiving surface side, an antireflection coating 3 made of silicon nitride, etc. is provided on the n⁺ diffusion layer 2, to a film thickness of approximately 90 nm, by PECVD, etc.

Next, a method for forming a light-receiving surface electrode 4 provided on the light-receiving surface side as outlined in FIG. 2, and a method for forming a collecting electrode 5 and a method for forming a power output electrode 6, which are formed on the back surface as outlined in FIG. 3, will be described.

A light-receiving surface electrode 4 and a back-surface power output electrode 6 are formed with the paste composition for an electrode according to the present invention. The back-surface collecting electrode 5 is formed with an aluminum electrode paste composition containing a glass powder.

A first example of the method for forming a light-receiving surface electrode 4, a back-surface collecting electrode 5, and a back-surface power output electrode 6, includes applying the paste composition by screen printing, etc. to form desired patterns, respectively, drying the same, and sintering the same simultaneously in the atmosphere at approximately 450° C. to 850° C. According to the present invention, by using the paste composition for an electrode, an electrode that exhibits superior resistivity and contact resistivity can be formed even if sintering is carried out at a relatively low temperature.

At that time, on the light-receiving surface side, glass particles contained in the paste composition for an electrode, which forms a light-receiving surface electrode 4, and an antireflection layer 3 are allowed to react (also referred to as fire-through). As a result, the light-receiving surface electrode 4 and an n⁺ diffusion layer 2 are electrically connected (ohmic contact).

According to the present invention, since a light-receiving surface electrode 4 is formed with the paste composition for an electrode, oxidation of copper is suppressed even though copper is included as a conductive metal. Therefore, a light-receiving surface electrode 4 with low resistivity can be formed at a high yield.

In the present invention, the electrode is preferably formed by including a Cu—Sn alloy phase and an Sn—P—O glass phase, and more preferably, the Sn—P—O glass phase is positioned between the Cu—Sn alloy phase and a silicon substrate (not illustrated). In that way, reaction between copper and a silicon substrate is suppressed, and an electrode that exhibits low resistance and superior adhesion can be formed.

On the back surface side, aluminum, which is contained in an aluminum electrode paste composition that forms a back-surface collecting electrode 5, diffuses into the back surface of a p-type silicon substrate 1 during sintering, thereby forming a p⁺ diffusion layer 7. In that way, an ohmic contact is obtained between the p-type silicon substrate 1 and a back-surface collecting electrode 5, and a back-surface power output electrode 6.

A second example of the method for forming a light-receiving surface electrode 4, a back-surface collecting electrode 5, and a back-surface power output electrode 6, includes performing printing with an aluminum electrode paste composition forming a back-surface collecting electrode 5, drying the same, and then sintering the same in the atmosphere at approximately 750° C. to 850° C., thereby forming a back-surface collecting electrode 5; and subsequently performing printing with the paste composition for an electrode according to the present invention on each of the light-receiving surface side and the back surface side, drying the same, and then sintering the same in the atmosphere at approximately 450° C. to 650° C., thereby forming a light-receiving surface electrode 4 and a back surface power output electrode 6.

This method is effective from the viewpoints as set forth below. Specifically, if sintering of an aluminum electrode paste is performed to form a back-surface collecting electrode 5 at a temperature of 650° C. or less, there may be cases in which formation of a p⁺ diffusion layer is insufficient and due to insufficient sintering of aluminum particles and insufficient diffusion of aluminum into the p-type silicon substrate 1, depending on the composition of the aluminum paste.

In such cases, formation of an ohmic contact between the p-type silicon substrate 1 on the back surface and the back-surface collecting electrode 5, or the back-surface power output electrode 6, may be insufficient. As a result, photovoltaic performances of a photovoltaic cell element may be lowered. Consequently, it is preferable to form the back-surface collecting electrode 5 at a sintering temperature that is suitable for an aluminum electrode paste composition (e.g. 750° C. to 850° C.), and subsequently form the light-receiving surface electrode 4 and the back-surface power output electrode 6 by performing printing with the paste composition for an electrode according to the present invention, drying the same, and then sintering the same at a relatively low temperature (450° C. to 650° C.).

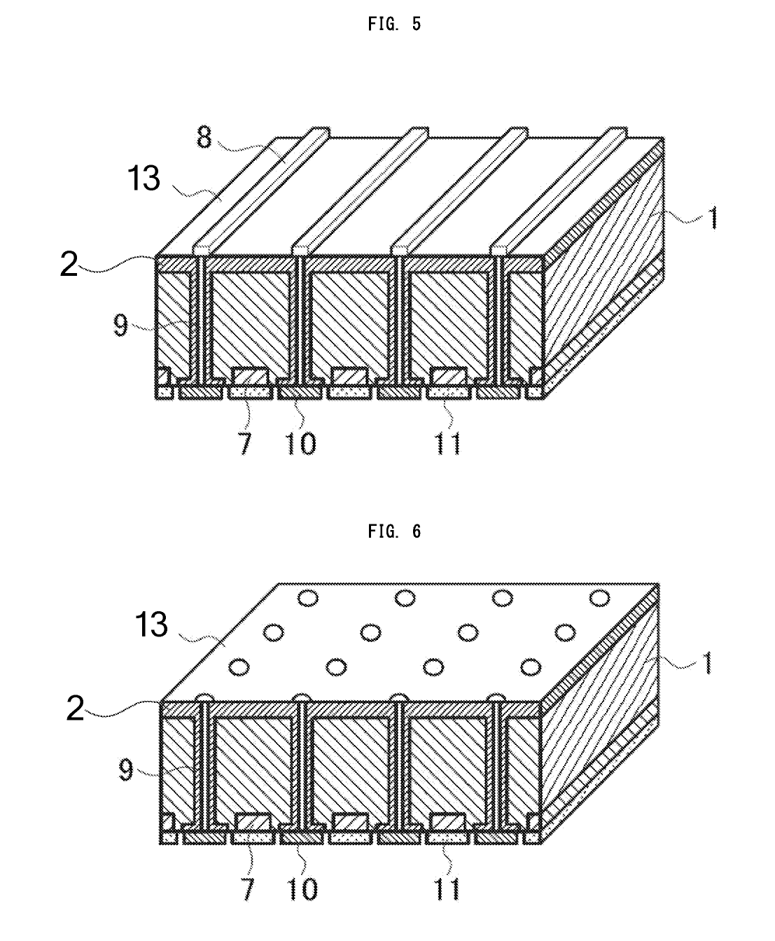

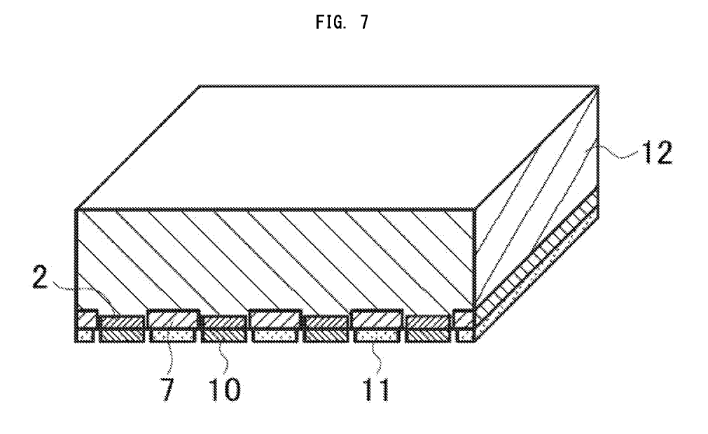

FIG. 4 shows a schematic plan view of the back-surface side electrode structure that is common to so-called back-contact type photovoltaic cell elements, which are another embodiment of the present invention. FIG. 5, FIG. 6 and FIG. 7 show perspective views of outlined structures of photovoltaic cell elements, respectively, which are different embodiments of back-contact type photovoltaic cell elements. The perspective views of FIG. 5, FIG. 6 and FIG. 7 each has a cross section at an AA-line shown in FIG. 4.

In a photovoltaic cell element having a structure shown in the perspective view of FIG. 5, through-holes, which penetrate from the light-receiving surface side to the back surface side, are formed in the p-type silicon substrate 1 by laser drilling or etching. Further, a texture (not illustrated) that enhances the light incidence efficiency is formed on the light-receiving surface side. In addition, an n⁺ diffusion layer 2 is formed on the light-receiving surface side by an n type diffusion treatment, and an antireflection coating 13 is formed on the n⁺ diffusion layer 2. These can be formed by the same process as that used for conventional crystalline Si-type photovoltaic cell elements.

Next, the through-holes formed in the above process are filled with the paste composition for an electrode according to the present invention by a printing method or an inkjet method. Further, printing is performed on the light-receiving surface side with the paste composition for an electrode according to the present invention into a grid form. A composition layer, which constitutes through-hole electrodes 9 and light-receiving surface collecting electrodes 8, is thus formed.

It is preferred to use a paste having an optimal composition for each process of filling and printing, such as viscosity. However, the filling and the printing may be carried out at once with a paste having the same composition.

On the back surface side, an n⁺ diffusion layer 2 and a p⁺ diffusion layer 7, which prevent recombination of carriers, are formed. The n⁺ diffusion layer 2, which is formed on the light-receiving surface side, portions surrounding the through holes and the back surface side, is formed so that it covers, in a continuous manner, from the light-receiving surface side to the portions surrounding the through holes, and from the portions surrounding the through holes to the back surface side. The n⁺ diffusion layer 2 may be formed on respective portions in different steps, or may be formed in the same step. Examples of impurity elements for forming the p⁺ diffusion layer 7 include boron (B) and aluminum (Al). The p⁺ diffusion layer 7 may be formed by, for example, exercising a thermal diffusion treatment with boron as a diffusion source during a production process of a photovoltaic cell element, prior to forming the antireflection coating 13. Alternatively, in a case in which aluminum is used, the p⁺ diffusion layer 7 may be formed by performing printing with an aluminum paste and sintering the same on the opposite surface side during the printing process.

On the back surface side, as shown in a plan view of FIG. 4, back surface electrodes 10 and 11 are formed by performing printing with the paste composition for an electrode according to the present invention into the form of stripes, on the n⁺ diffusion layer 2 and the p⁺ diffusion layer 7, respectively. In a case in which the p⁺ diffusion layer 7 is formed with an aluminum paste, it is enough that back surface electrodes are formed with the paste composition for an electrode according to the present invention only on the n⁺ diffusion layer 2.

Followed by drying and sintering the paste composition in the atmosphere at approximately 450° C. to 850° C., light-receiving surface collecting electrodes 8, through-hole electrodes 9, and back surface electrodes 10 and 11 are formed. In a case in which an aluminum electrode is used for either one of back surface electrodes, as mentioned above, it is also possible to form one of the back surface electrodes by performing printing and sintering with an aluminum paste, and subsequently perform printing, filling and sintering with the paste composition for an electrode according to the present invention, thereby forming light-receiving surface collecting electrodes 8, through-hole electrodes 9, and the other one of back surface electrodes, from the viewpoints of sintering properties of aluminum and ohmic contact properties of the back surface electrodes and the p⁺ diffusion layer 7.

A photovoltaic cell element, having a structure shown as a perspective view of FIG. 6, can be produced in a similar manner to the production of photovoltaic cell elements having a structure shown as a perspective view of FIG. 5, except that the light-receiving surface collecting electrode is not formed. Specifically, in a photovoltaic cell element having a structure shown as a perspective view of FIG. 6, the paste composition for an electrode according to the present invention can be used for through-hole electrodes 9 and back surface electrodes 10 and 11.

A photovoltaic cell element, shown as a perspective view of FIG. 7, has a structure in which an n-type silicon substrate 12 is used as a basic substrate and, on the back surface side, an n⁺ diffusion layer 2 and a p⁺ diffusion layer 7 are formed. The n⁺ diffusion layer 2 and the p⁺ diffusion layer 7 may be formed in a similar manner to those of a photovoltaic cell element having a structure shown as a perspective view of FIG. 5. Further, on the back surface side, as shown in a plan view of FIG. 4, back surface electrodes 10 and 11 are formed by performing printing with the paste composition for an electrode according to the present invention into the form of stripes, on the n⁺ diffusion layer 2 and the p⁺ diffusion layer 7, respectively. In a case in which the p⁺ diffusion layer 7 is formed with an aluminum paste, it is enough that back surface electrodes are formed with the paste composition for an electrode according to the present invention only on the n⁺ diffusion layer 2.

Applications of the paste composition for an electrode according to the present invention are not limited to photovoltaic cell electrodes as described above, and suitable examples thereof include electrode wiring and shield wiring for plasma displays, ceramic capacitors, antenna circuits, sensor circuits of various types, and heat radiating materials for semiconductor devices.

In particular, the paste composition for an electrode according to the invention can be favorably used for forming electrodes on a substrate containing silicon.

[Photovoltaic Cell]

A photovoltaic cell according to the present invention includes at least one of the photovoltaic cell element and a tab wire that is positioned on an electrode of the photovoltaic cell element. The photovoltaic cell may have a structure that includes plural photovoltaic cell elements that are connected to each other with tab wires, and is sealed with a sealing material.

The tab wire and the sealing material are not particularly restricted, and may be selected from any products that are common in the art.

### EXAMPLES

The present invention will be described more specifically with reference to the examples. However, the present invention is not limited thereto. The expressions “part” and “%” are by mass, unless otherwise specified. With regard to the composition of phosphorus-tin-containing copper alloy particles, for example, Cu-AX-BY-CZ refers to that A mass % of element X, B mass % of element Y, and Class % of element Z are contained in a copper alloy.

### Example 1

### (a) Preparation of Paste Composition for Electrode

Phosphorus-tin-containing copper alloy particles containing 6 mass % of phosphorus and 10 mass % of tin were prepared, and were melted and powderized by a water atomization process. The obtained powder was dried and classified. The classified powder was blended, and was subjected to deoxidation and dehydration treatments, whereby phosphorus-tin-containing copper alloy particles that contain 6 mass % of phosphorus and 10 mass % of tin were prepared. The particle size (D50%) of the phosphorus-tin-containing copper alloy particles was 5.0 μm, and the shape was quasispherical.

A glass (hereinafter, also referred to “G01”) composed of silicon dioxide (SiO₂) (3 parts), lead oxide (PbO) (60 parts), boron oxide (B₂O₃) (18 parts), bismuth oxide (Bi₂O₃) (5 parts), aluminum oxide (Al₂O₃) (5 parts), and zinc oxide (ZnO) (9 parts) was prepared. The obtained G01 had a softening point of 420° C., and the crystallization temperature was above 650° C.

With the obtained G01, particles having a particle size (D50%) of 2.5 μm were produced. The shape of the particles was quasispherical.

The obtained phosphorus-tin-containing copper alloy particles (81.4 parts), G01 particles (4.1 parts), terpineol (Ter) (14.1 parts), and ethylcellulose (EC) (0.4 parts) were blended and milled in an agate mortar for 20 minutes, thereby preparing a paste composition for an electrode 1.

### (b) Production of Photovoltaic Cell Element

A p-type semiconductor substrate having a thickness of 190 μm, in which an n⁺ diffusion layer and an antireflection coating (silicon nitride film) were formed on the textured light-receiving surface, was prepared. A specimen having the size of 125 mm×125 mm was obtained from the p-type semiconductor substrate. On the light-receiving surface, the paste composition for an electrode 1, obtained in the above process, was provided by a screen printing method to form an electrode pattern as shown in FIG. 2. Printing conditions (screen mesh size, printing speed, and printing pressure) were adjusted so that the electrode pattern include 150 μm-wide finger lines and 1.5 mm-wide bus bars, and have a thickness after sintering of 20 μm. The specimen was placed in an oven heated to 150° C. for 15 min, and the solvent was allowed to evaporate.

Next, an electrode pattern as shown in FIG. 3 was formed on the back surface of the p-type semiconductor substrate with the paste composition for an electrode 1 and an aluminum electrode paste by a screen printing method similar to the above.

The pattern of the back-surface power output electrode, formed with the paste composition for an electrode 1, was constituted of two electrodes each having the size of 123 mm×5 mm. The printing conditions (screen mesh size, printing speed, and printing pressure) were adjusted appropriately so that the thickness of the back surface power output electrode after sintering was 20 μm. The aluminum electrode paste was provided by printing on the whole surface except for the back surface power output electrodes, thereby forming a back-surface collecting electrode pattern. The printing conditions for the aluminum electrode paste were adjusted appropriately so that the thickness of the back-surface collecting electrode after sintering was 30 μm. The specimen was placed in an oven heated to 150° C. for 15 min, and the solvent was allowed to evaporate.

Next, the p-type semiconductor substrate was subjected to a heat treatment (sintering) with a tunnel oven (single-line conveyer W/B tunnel oven, manufactured by Noritake Co., Limited) in the atmosphere for a retention time of 10 seconds at a maximum sintering temperature of 800° C., thereby preparing a photovoltaic cell element 1 having a desired electrode formed thereon.

### Example 2

A photovoltaic cell element 2 was produced in a similar manner to Example 1, except that the sintering conditions for forming an electrode was changed from 10 seconds at a maximum temperature of 800° C. to 8 seconds at a maximum temperature of 850° C.

### Example 3

A photovoltaic cell element 3 was produced in a similar manner to Example 1, except that a paste composition for an electrode 3 was produced by changing the phosphorus content of the phosphorus-tin-containing copper alloy particles from 6 mass % to 5 mass %, and by changing the tin content of the phosphorus-tin-containing copper alloy particles from 10 mass % to 15 mass %.

### Example 4

A photovoltaic cell element 4 was produced in a similar manner to Example 3, except that the sintering conditions for forming an electrode was changed from 10 seconds at a maximum temperature of 800° C. to 8 seconds at a maximum temperature of 850° C.

### Example 5

A photovoltaic cell element 5 was produced in a similar manner to Example 1, except that a paste composition for an electrode 5 was prepared by adding silver to the phosphorus-tin-containing copper alloy particles, thereby changing the composition to Cu-6P-15Sn-1Ag.

### Example 6

A photovoltaic cell element 6 was produced in a similar manner to Example 1, except that a paste composition for an electrode 6 was prepared by adding silver to the phosphorus-tin-containing copper alloy particles, thereby changing the composition to Cu-6P-15Sn-5Ag.

### Example 7

A photovoltaic cell element 7 was produced in a similar manner to Example 1, except that a paste composition for an electrode 6 was prepared by adding silver to the phosphorus-tin-containing copper alloy particles, thereby changing the composition to Cu-6P-15Sn-10Ag.

### Example 8

A photovoltaic cell element 8 was produced in a similar manner to Example 1, except that a paste composition for an electrode 8 was prepared by adding manganese to the phosphorus-tin-containing copper alloy particles, thereby changing the composition to Cu-6P-15Sn-2Mn.

### Example 9

A photovoltaic cell element 9 was produced in a similar manner to Example 1, except that a paste composition for an electrode 9 was prepared by adding cobalt to the phosphorus-tin-containing copper alloy particles, thereby changing the composition to Cu-6P-15Sn-2Co.

### Example 10

A photovoltaic cell element 10 was produced in a similar manner to Example 1, except that a paste composition for an electrode 10 was prepared by changing the particle size of the phosphorus-tin-containing copper alloy particles from 5.0 μm to 1.5 μm.

### Example 11

A photovoltaic cell element 11 was produced in a similar manner to Example 1, except that a paste composition for an electrode 11 was prepared by adding silver particles (particle size (D50%): 3.0 μm, purity: 99.5%) to the paste composition for an electrode, such that the content of each component was 77.4 parts for the phosphorus-tin-containing copper alloy particles, 4.0 parts for the silver particles, 4.1 parts for the glass particles, 14.1 parts for the solvent, and 0.4 parts for the resin.

### Example 12

A photovoltaic cell element 12 was produced in a similar manner to Example 1, except that a paste composition for an electrode 12 was prepared by adding silver particle (particle size (D50%): 3.0 μm, purity: 99.5%) to the paste composition for an electrode, such that the content of each component was 73.4 parts for the phosphorus-tin-containing copper alloy particles, 8.0 parts for the silver particles, 4.1 parts for the glass particles, 14.1 parts for the solvent, and 0.4 parts for the resin.

### Example 13

A photovoltaic cell element 13 was produced in a similar manner to Example 1, except that a paste composition for an electrode 13 was prepared by changing the phosphorus content of the phosphorus-tin-containing copper alloy particles from 6 mass % in Example 1 to 10 mass %, and by changing the tin content of the phosphorus-tin-containing copper alloy particles from 10 mass % to 20 mass %.

### Example 14

A photovoltaic cell element 14 was produced in a similar manner to Example 13, except that the sintering conditions for forming an electrode was changed from 10 seconds at the maximum temperature of 800° C. to 8 seconds at the maximum temperature of 850° C.

### Example 15

A photovoltaic cell element 15 was produced in a similar manner to Example 15, except that the sintering conditions for forming an electrode was changed from 10 seconds at the maximum temperature of 800° C. to 12 seconds at the maximum temperature of 750° C.

### Example 16

A photovoltaic cell element 16 was produced in a similar manner to Example 1, except that a paste composition for an electrode 16 was prepared by changing the composition of the glass particles from glass G01 to glass G02 as described below.

A glass G02 was prepared to have a composition of vanadium oxide (V₂O₅) (45 parts), phosphorus oxide (P₂O₅) (24.2 parts), barium oxide (BaO) (20.8 parts), antimony oxide (Sb₂O₃) (5 parts), and tungsten oxide (WO₃) (5 parts). The softening point of the glass G02 was 492° C., and the crystallization initiation temperature was above 650° C.

With the obtained glass G02, glass G02 particles with the particle size (D50%) of 2.5 μm were prepared. The shape was quasispherical.

### Example 17

A photovoltaic cell element 17 was produced in a similar manner to Example 16, except that a paste composition for an electrode 17 was prepared by changing the content of the phosphorus-tin-containing copper alloy particles from 81.4 mass % to 79.0 mass %, and by changing the content of the glass G02 particles from 4.1 mass % to 6.5 mass %.

### Example 18

A photovoltaic cell element 18 was produced in a similar manner to Example 1, except that a paste composition for an electrode 18 was prepared by changing the solvent from terpineol to diethylene glycol monobutyl ether (BC), and changing the resin from ethyl cellulose to poly(ethyl acrylate) (EPA), respectively. More specifically, the content of each component was changed to 81.4 parts for the phosphorus-tin-containing copper alloy particles, 4.1 parts for the glass G01 particles, 12.3 parts for diethylene glycol monobutyl ethers and 2.2 parts for poly(ethyl acrylate).

### Examples 19 to 23

Paste compositions 19 to 23 for an electrode were prepared in a similar manner to Example 1, except that the phosphorus content, the tin content, the silver content, the manganese content, the cobalt content and the particle size (D50%) of the phosphorus-tin-containing copper alloy particles, the content of the phosphorus-tin-containing copper alloy particles, the content of the silver particles, the type and the content of the glass particles, the type and the content of the solvent, and the type and the content of the resin were changed to that as shown in Table 1.

Subsequently, photovoltaic cell elements 19 to 23 were prepared in a similar manner to Example 1, respectively, except that the temperature and the treatment time for the heat treatment were changed to that as shown in Table 1.

### Example 24

A p-type semiconductor substrate having a thickness of 190 μm, in which an n⁺ diffusion layer and an antireflection coating (silicon nitride film) were formed on the textured light-receiving surface, was prepared. A specimen having the size of 125 mm×125 mm was obtained from the p-type semiconductor substrate. Thereafter, a back-surface collecting electrode pattern was formed on the back surface with an aluminum electrode paste. The back-surface collecting electrode pattern was formed on the entire region other than the back-surface power output electrodes, as shown in FIG. 3. The printing conditions (screen mesh size, printing speed, and printing pressure) were adjusted so that back-surface collecting electrodes have a thickness after sintering of 30 μm. The specimen was placed in an oven heated to 150° C. for 15 min, and the solvent was allowed to evaporate.

Next, the p-type semiconductor substrate was subjected to a heat treatment (sintering) with a tunnel oven (single-line conveyer W/B tunnel oven, manufactured by Noritake Co., Limited) in the atmosphere for a retention time of 10 seconds at a maximum sintering temperature of 800° C., thereby preparing back-surface collecting electrodes and a p⁺-type diffusion layer.

Subsequently, electrode patterns shown in FIGS. 2 and 3 were formed from a paste composition for an electrode 1 by printing. The electrode pattern on the light-receiving surface was constituted of 150 μm-wide finger lines and 1.5 mm-wide bus bars, and the printing conditions (screen mesh size, printing speed, and printing pressure) were adjusted such that the thickness after sintering was 20 μm. The electrode pattern on the back surface was constituted of 123 mm×5 mm, and was printed at two portions, such that the thickness after sintering was 20 μm. The specimen was placed in an oven heated to 150° C. for 15 min, and the solvent was allowed to evaporate.

A photovoltaic cell element 24, provided with electrodes, was prepared by subjecting the specimen to a heat treatment (sintering) with a tunnel oven (single-line conveyor W/B tunnel oven, manufactured by Noritake Co., Limited) in the atmosphere for the retention time of 10 seconds at the maximum sintering temperature of 650° C.

### Example 25

A photovoltaic cell element 25 was produced in a similar manner to Example 24, except that the paste composition for an electrode 7 was used for forming the light-receiving surface electrode and the back-surface power output electrode.

### Example 26

A photovoltaic cell element 26 was produced in a similar manner to Example 24, except that the paste composition for an electrode 11 was used for forming the light-receiving surface electrode and the back-surface power output electrode.

### Example 27

A photovoltaic cell element 27, having a structure as shown in FIG. 5, was produced with the paste composition for an electrode 1.

Specifically, through-holes penetrating from the light-receiving surface side to the back surface side, and having a diameter of 100 μm, were formed in the p-type silicon substrate with a laser drill. Further, a texture, an n⁺ diffusion layer, and an antireflection coating were formed on the light-receiving surface side, in this order. The n⁺ diffusion layer was formed also on inner sides of the through holes and a portion of the back surface. Then, the through-holes were filled with the paste composition for an electrode 1 by an inkjet method, and a grid pattern was formed with the paste composition for an electrode 1 on the light-receiving surface side.

On the back surface side, a striped pattern shown in FIG. 4 was formed with the paste composition for an electrode 1 and an aluminum electrode paste, such that the paste composition for an electrode 1 was printed below the through-holes. This was subjected to a heat treatment with a tunnel oven (single-line WB conveyor tunnel oven, manufactured by Noritake Co., Limited) in the atmosphere for a retention time of 10 seconds at a maximum sintering temperature of 800° C., thereby producing a photovoltaic cell element 27 having electrodes formed thereon.

During sintering, a p⁺ diffusion layer was formed by allowing aluminum to diffuse into the p-type silicon substrate, at a portion on which the aluminum electrode paste was formed.

### Example 28

A photovoltaic cell element 28 was produced in a similar manner to Example 27, except that the sintering conditions for forming an electrode was changed from 10 seconds at a maximum temperature of 800° C. to 8 seconds at a maximum temperature of 850° C.

### Example 29

A photovoltaic cell element 29 was produced in a similar manner to Example 27, except that the light-receiving surface collecting electrode, the through-hole electrodes, and the back surface electrodes were formed with the paste composition for an electrode 12 instead of the paste composition for an electrode 1.

### Example 30

A paste composition for an electrode 30 was prepared in a similar manner to Example 1, except that the glass G01 particles were changed to glass G03 particles.

A glass G03 was prepared so as to have a composition of silicon dioxide (SiO₂) (13 parts), boron oxide (B₂O₃) (58 parts), zinc oxide (ZnO) (38 parts), aluminum oxide (Al₂O₃) (12 parts) and barium oxide (BaO) (12 parts). The softening point of the obtained glass G03 was 583° C., and the crystallization initiation temperature was above 650° C.

Glass G03 particles, having a particle size (D50%) of 2.5 μm, were obtained with glass G03. The shape was quasispherical.

Then, a photovoltaic cell element 30, having a structure as shown in FIG. 6, was produced with the paste composition for an electrode 30. The production method was similar to that of Examples 27 to 29, except that the light-receiving surface electrode was not formed. The sintering was carried out for a retention time of 10 seconds at a maximum temperature of 800° C.

### Example 31

A photovoltaic cell element 31 was produced in a similar manner to Example 30, except that the sintering conditions for forming an electrode were changed from 10 seconds at a maximum temperature of 800° C. to 8 seconds at a maximum temperature of 850° C.

### Example 32

A paste composition for an electrode 32 was prepared in a similar manner to Example 13, except that the glass G01 was changed to the glass G03. A photovoltaic cell element 32, having a structure shown in FIG. 6, was produced in a similar manner to Example 30, except that the paste composition for an electrode 32 was used.

### Example 33

A photovoltaic cell element 33, having a structure as shown in FIG. 7, was produced with the paste composition for an electrode 30. The production method was similar to that of Example 27, except that an n-type silicon substrate was used as a basic substrate, and that the light-receiving surface electrode, the through-holes and the through-hole electrodes were not formed. The sintering was carried out for a retention time of 10 seconds at a maximum temperature of 800° C.

### Example 34

A photovoltaic cell element 34 was produced in a similar manner to Example 33, except that the sintering conditions for forming an electrode was changed from 10 seconds at a maximum temperature of 800° C. to 8 seconds at a maximum temperature of 850° C.

### Example 35

A paste composition for an electrode 35 was prepared in a similar manner to Example 13, except that the glass G01 particles were changed to the glass G03 particles. A photovoltaic cell element 35, having a structure shown in FIG. 7, was produced in a similar manner to Example 33.

### Comparative Example 1

A paste composition for an electrode C1 was prepared in a similar manner to Example 1, except that the phosphorus-tin-containing copper alloy particles were not used and the composition was changed to that as shown in Table 1.

A photovoltaic cell element C1 was produced in a similar manner to Example 1, except that the paste composition for an electrode C1, not containing phosphorus-tin-containing copper alloy particles, was used.

### Comparative Examples 2 to 4

Paste compositions for an electrode C2 to C4, having the compositions as shown in Table 1, were prepared by using copper particles (purity: 99.5%), phosphorus-containing copper alloy particles or tin-containing copper alloy particles, instead of the phosphorus-tin-containing copper alloy particles.

Photovoltaic cell elements C2 to C4 were produced in a similar manner to Comparative Example 1, except that the paste compositions for an electrode C2 to C4 were used, respectively.

### Comparative Example 5

A photovoltaic cell element C5 was produced in a similar manner to Example 27, except that the light-receiving surface collecting electrode, the through-hole electrode, and the back-surface electrode were formed with the paste composition for an electrode C1 instead of the paste composition for an electrode 1.

### Comparative Example 6

A photovoltaic cell element C6 was produced in a similar manner to Example 30, except that the paste composition for an electrode 30 was changed to the paste composition for an electrode C1.

### Comparative Example 7

A photovoltaic cell element C7 was produced in a similar manner to Example 33, except that the paste composition for an electrode 33 was changed to the paste composition for an electrode C1.

TABLE 1

| | Phosphorus-tin-containing copper alloy particles | | | | | | | Silver particles | | Glass particles | | | | | | |
|---|---|---|---|---|---|---|---|---|---|---|---|---|---|---|---|---|
| | | | | | | Particle | | Particle | | | Particle | | Solvent | | Resin | |
| | P | Sn | Other components | | | size | | size | | | size | | | Con- | | Con- |
| | content | content | Ag | Mn | Co | (D50%) | Content | (D50%) | Content | | (D50%) | Content | | tent | | tent |
| | (wt %) | (wt %) | (%) | (%) | (%) | (m) | (part) | (m) | (part) | Type | (m) | (part) | Type | (part) | Type | (part) |
| Example 1 | 6 | 10 | 0 | 0 | 0 | 5.0 | 81.4 | — | — | G01 | 2.5 | 4.1 | Ter | 14.1 | EC | 0.4 |
| Example 2 | 6 | 10 | 0 | 0 | 0 | 5.0 | 81.4 | — | — | G01 | 2.5 | 4.1 | Ter | 14.1 | EC | 0.4 |
| Example 3 | 5 | 15 | 0 | 0 | 0 | 5.0 | 81.4 | — | — | G01 | 2.5 | 4.1 | Ter | 14.1 | EC | 0.4 |
| Example 4 | 5 | 15 | 0 | 0 | 0 | 5.0 | 81.4 | — | — | G01 | 2.5 | 4.1 | Ter | 14.1 | EC | 0.4 |
| Example 5 | 6 | 15 | 1 | 0 | 0 | 5.0 | 81.4 | — | — | G01 | 2.5 | 4.1 | Ter | 14.1 | EC | 0.4 |
| Example 6 | 6 | 15 | 5 | 0 | 0 | 5.0 | 81.4 | — | — | G01 | 2.5 | 4.1 | Ter | 14.1 | EC | 0.4 |
| Example 7 | 6 | 15 | 10 | 0 | 0 | 5.0 | 81.4 | — | — | G01 | 2.5 | 4.1 | Ter | 14.1 | EC | 0.4 |
| Example 8 | 6 | 15 | 0 | 2 | 0 | 5.0 | 81.4 | — | — | G01 | 2.5 | 4.1 | Ter | 14.1 | EC | 0.4 |
| Example 9 | 6 | 15 | 0 | 0 | 2 | 5.0 | 81.4 | — | — | G01 | 2.5 | 4.1 | Ter | 14.1 | EC | 0.4 |
| Example 10 | 6 | 10 | 0 | 0 | 0 | 1.5 | 81.4 | — | — | G01 | 2.5 | 4.1 | Ter | 14.1 | EC | 0.4 |
| Example 11 | 6 | 10 | 0 | 0 | 0 | 1.5 | 77.4 | 3.0 | 4.0 | G01 | 2.5 | 4.1 | Ter | 14.1 | EC | 0.4 |
| Example 12 | 6 | 10 | 0 | 0 | 0 | 1.5 | 73.4 | 3.0 | 8.0 | G01 | 2.5 | 4.1 | Ter | 14.1 | EC | 0.4 |
| Example 13 | 10 | 20 | 0 | 0 | 0 | 5.0 | 81.4 | — | — | G01 | 2.5 | 4.1 | Ter | 14.1 | EC | 0.4 |
| Example 14 | 10 | 20 | 0 | 0 | 0 | 5.0 | 81.4 | — | — | G01 | 2.5 | 7.8 | Ter | 14.1 | EC | 0.4 |
| Example 15 | 10 | 20 | 0 | 0 | 0 | 5.0 | 81.4 | — | — | G01 | 2.5 | 4.1 | Ter | 14.1 | EC | 0.4 |
| Example 16 | 6 | 10 | 0 | 0 | 0 | 5.0 | 81.4 | — | — | G02 | 2.5 | 4.1 | Ter | 14.1 | EC | 0.4 |
| Example 17 | 6 | 10 | 0 | 0 | 0 | 5.0 | 79.0 | — | — | G02 | 2.5 | 6.5 | Ter | 14.1 | EC | 0.4 |
| Example 18 | 6 | 10 | 0 | 0 | 0 | 5.0 | 81.4 | — | — | G01 | 2.5 | 4.1 | BC | 12.3 | EPA | 2.2 |
| Example 19 | 6 | 10 | 2 | 0 | 0 | 1.5 | 77.9 | 3.0 | 3.5 | G01 | 2.5 | 4.1 | Ter | 14.1 | EC | 0.4 |
| Example 20 | 10 | 15 | 0 | 3 | 0 | 5.0 | 75.4 | 3.0 | 2.0 | G01 | 2.5 | 4.1 | Ter | 14.1 | EC | 0.4 |
| Example 21 | 6 | 9 | 0 | 0 | 4 | 5.0 | 81.4 | — | — | G02 | 2.5 | 4.1 | BC | 12.3 | EPA | 2.2 |
| Example 22 | 5 | 15 | 0 | 3 | 0 | 5.0 | 77.4 | 3.0 | 4.0 | G02 | 2.5 | 4.1 | BC | 12.3 | EPA | 2.2 |
| Example 23 | 5 | 15 | 0 | 3 | 0 | 5.0 | 79.0 | 3.0 | 4.0 | G02 | 2.5 | 6.5 | BC | 12.3 | EPA | 2.2 |
| Example 24 | 6 | 10 | 0 | 0 | 0 | 5.0 | 81.4 | — | — | G01 | 2.5 | 4.1 | Ter | 14.1 | EC | 0.4 |

| | | Electrodes | | | | | | | | Sintering conditions | |
|---|---|---|---|---|---|---|---|---|---|---|---|
| | | | Light- | | | | | Sintering conditions | | for paste composition | |
| | | Light- | receiving | Back | | | | for Al paste | | for electrode | |
| | | receiving | surface | surface | | | | Maximum | | Maximum | |
| | | surface | power | power | Through- | Back | Only Al | temper- | | temper- | |
| | Photovoltaic | collecting | output | output | hole | surface | electrode | ature | Retention | ature | Retention |
| | cell structure | electrode | electrode | electrode | electrode | electrode | formed | [° C.] | time [sec] | [° C.] | time [sec] |
| Example 1 | Double-sided | ◯ | ◯ | ◯ | — | — | — | — | — | 800 | 10 |
| Example 2 | Double-sided | ◯ | ◯ | ◯ | — | — | — | — | — | 850 | 8 |
| Example 3 | Double-sided | ◯ | ◯ | ◯ | — | — | — | — | — | 800 | 10 |
| Example 4 | Double-sided | ◯ | ◯ | ◯ | — | — | — | — | — | 850 | 8 |
| Example 5 | Double-sided | ◯ | ◯ | ◯ | — | — | — | — | — | 800 | 10 |
| Example 6 | Double-sided | ◯ | ◯ | ◯ | — | — | — | — | — | 800 | 10 |
| Example 7 | Double-sided | ◯ | ◯ | ◯ | — | — | — | — | — | 800 | 10 |
| Example 8 | Double-sided | ◯ | ◯ | ◯ | — | — | — | — | — | 800 | 10 |
| Example 9 | Double-sided | ◯ | ◯ | ◯ | — | — | — | — | — | 800 | 10 |
| Example 10 | Double-sided | ◯ | ◯ | ◯ | — | — | — | — | — | 800 | 10 |
| Example 11 | Double-sided | ◯ | ◯ | ◯ | — | — | — | — | — | 800 | 10 |
| Example 12 | Double-sided | ◯ | ◯ | ◯ | — | — | — | — | — | 800 | 10 |
| Example 13 | Double-sided | ◯ | ◯ | ◯ | — | — | — | — | — | 800 | 10 |
| Example 14 | Double-sided | ◯ | ◯ | ◯ | — | — | — | — | — | 850 | 8 |
| Example 15 | Double-sided | ◯ | ◯ | ◯ | — | — | — | — | — | 750 | 12 |
| Example 16 | Double-sided | ◯ | ◯ | ◯ | — | — | — | — | — | 800 | 10 |
| Example 17 | Double-sided | ◯ | ◯ | ◯ | — | — | — | — | — | 800 | 10 |
| Example 18 | Double-sided | ◯ | ◯ | ◯ | — | — | — | — | — | 800 | 10 |
| Example 19 | Double-sided | ◯ | ◯ | ◯ | — | — | — | — | — | 800 | 10 |
| Example 20 | Double-sided | ◯ | ◯ | ◯ | — | — | — | — | — | 850 | 8 |
| Example 21 | Double-sided | ◯ | ◯ | ◯ | — | — | — | — | — | 800 | 10 |
| Example 22 | Double-sided | ◯ | ◯ | ◯ | — | — | — | — | — | 800 | 10 |
| Example 23 | Double-sided | ◯ | ◯ | ◯ | — | — | — | — | — | 800 | 10 |
| Example 24 | Double-sided | ◯ | ◯ | ◯ | — | — | ◯ | 800 | 10 | 650 | 10 |

| | Phosphorus-tin-containing copper alloy particles | | | | | | | Silver particles | | Glass particles | | | | | | |
|---|---|---|---|---|---|---|---|---|---|---|---|---|---|---|---|---|
| | | | | | | Particle | | Particle | | | Particle | | Solvent | | Resin | |
| | P | Sn | Other components | | | size | | size | | | size | | | Con- | | Con- |
| | content | content | Ag | Mn | Co | (D50%) | Content | (D50%) | Content | | (D50%) | Content | | tent | | tent |
| | (wt %) | (wt %) | (%) | (%) | (%) | (m) | (part) | (m) | (part) | Type | (m) | (part) | Type | (part) | Type | (part) |
| Example 25 | 6 | 15 | 10 | 0 | 0 | 5.0 | 81.4 | — | — | G01 | 2.5 | 4.1 | Ter | 14.1 | EC | 0.4 |
| Example 26 | 6 | 10 | 0 | 0 | 0 | 1.5 | 77.4 | 3.0 | 4.0 | G01 | 2.5 | 4.1 | Ter | 14.1 | EC | 0.4 |
| Example 27 | 6 | 10 | 0 | 0 | 0 | 5.0 | 81.4 | — | — | G01 | 2.5 | 4.1 | Ter | 14.1 | EC | 0.4 |
| Example 28 | 6 | 10 | 0 | 0 | 0 | 5.0 | 81.4 | — | — | G01 | 2.5 | 4.1 | Ter | 14.1 | EC | 0.4 |
| Example 29 | 6 | 10 | 0 | 0 | 0 | 1.5 | 73.4 | 3.0 | 8.0 | G01 | 2.5 | 4.1 | Ter | 14.1 | EC | 0.4 |
| Example 30 | 6 | 10 | 0 | 0 | 0 | 5.0 | 81.4 | — | — | G03 | 2.5 | 4.1 | Ter | 14.1 | EC | 0.4 |
| Example 31 | 6 | 10 | 0 | 0 | 0 | 5.0 | 81.4 | — | — | G03 | 2.5 | 4.1 | Ter | 14.1 | EC | 0.4 |
| Example 32 | 10 | 20 | 0 | 0 | 0 | 5.0 | 81.4 | — | — | G03 | 2.5 | 4.1 | Ter | 14.1 | EC | 0.4 |
| Example 33 | 6 | 10 | 0 | 0 | 0 | 5.0 | 81.4 | — | — | G03 | 2.5 | 4.1 | Ter | 14.1 | EC | 0.4 |
| Example 34 | 6 | 10 | 0 | 0 | 0 | 5.0 | 81.4 | — | — | G03 | 2.5 | 4.1 | Ter | 14.1 | EC | 0.4 |
| Example 35 | 10 | 20 | 0 | 0 | 0 | 5.0 | 81.4 | — | — | G03 | 2.5 | 4.1 | Ter | 14.1 | EC | 0.4 |
| Comp. Ex. 1 | — | — | — | — | — | — | — | 3.0 | 81.4 | G01 | 2.5 | 4.1 | Ter | 14.1 | EC | 0.4 |
| Comp. Ex. 2 | — | — | — | — | — | — | — | 3.0 | 81.4 | G01 | 2.5 | 4.1 | Ter | 14.1 | EC | 0.4 |
| Comp. Ex. 3 | 0 | 0 | 0 | 0 | 0 | 5.0 | 81.4 | — | — | G01 | 2.5 | 4.1 | Ter | 14.1 | EC | 0.4 |
| Comp. Ex. 4 | 6 | 0 | 0 | 0 | 0 | 5.0 | 81.4 | — | — | G01 | 2.5 | 4.1 | Ter | 14.1 | EC | 0.4 |
| Comp. Ex. 5 | 0 | 30 | 0 | 0 | 0 | 5.0 | 81.4 | 3.0 | 81.4 | G01 | 2.5 | 4.1 | Ter | 14.1 | EC | 0.4 |
| Comp. Ex. 6 | — | — | — | — | — | — | — | 3.0 | 81.4 | G01 | 2.5 | 4.1 | Ter | 14.1 | EC | 0.4 |
| Comp. Ex. 7 | — | — | — | — | — | — | — | 3.0 | 81.4 | G01 | 2.5 | 4.1 | Ter | 14.1 | EC | 0.4 |
| Comp. Ex. 8 | — | — | — | — | — | — | — | 3.0 | 81.4 | G01 | 2.5 | 4.1 | Ter | 14.1 | EC | 0.4 |
| Comp. Ex. 9 | — | — | — | — | — | — | — | 3.0 | 81.4 | G01 | 2.5 | 4.1 | Ter | 14.1 | EC | 0.4 |
| Comp. Ex. 10 | — | — | — | — | — | — | — | 3.0 | 81.4 | G01 | 2.5 | 4.1 | Ter | 14.1 | EC | 0.4 |
| Comp. Ex. 11 | — | — | — | — | — | — | — | 3.0 | 81.4 | G01 | 2.5 | 4.1 | Ter | 14.1 | EC | 0.4 |

| | | Electrodes | | | | | | | | Sintering conditions | |
|---|---|---|---|---|---|---|---|---|---|---|---|
| | | | Light- | | | | | Sintering conditions | | for paste composition | |
| | | Light- | receiving | Back | | | | for Al paste | | for electrode | |
| | | receiving | surface | surface | | | | Maximum | | Maximum | |
| | | surface | power | power | Through- | Back | Only Al | temper- | | temper- | |
| | Photovoltaic | collecting | output | output | hole | surface | electrode | ature | Retention | ature | Retention |
| | cell structure | electrode | electrode | electrode | electrode | electrode | formed | [° C.] | time [sec] | [° C.] | time [sec] |
| Example 25 | Double-sided | ◯ | ◯ | ◯ | — | — | — | — | — | 650 | 10 |
| Example 26 | Double-sided | ◯ | ◯ | ◯ | — | — | — | — | — | 650 | 10 |
| Example 27 | Back-contact | ◯ | — | — | ◯ | ◯ | — | — | — | 800 | 10 |
| Example 28 | Back-contact | ◯ | — | — | ◯ | ◯ | — | — | — | 850 | 8 |
| Example 29 | Back-contact | ◯ | — | — | ◯ | ◯ | — | — | — | 800 | 10 |
| Example 30 | Back-contact | — | — | — | ◯ | ◯ | — | — | — | 800 | 10 |
| Example 31 | Back-contact | — | — | — | ◯ | ◯ | — | — | — | 850 | 8 |
| Example 32 | Back-contact | — | — | — | ◯ | ◯ | — | — | — | 800 | 10 |
| Example 33 | Back-contact | — | — | — | — | ◯ | — | — | — | 800 | 10 |
| Example 34 | Back-contact | — | — | — | — | ◯ | — | — | — | 850 | 8 |
| Example 35 | Back-contact | — | — | — | — | ◯ | — | — | — | 800 | 10 |
| Comp. Ex. 1 | Double-sided | ◯ | ◯ | ◯ | — | — | — | — | — | 800 | 10 |
| Comp. Ex. 2 | Double-sided | ◯ | ◯ | ◯ | — | — | — | — | — | 850 | 8 |
| Comp. Ex. 3 | Double-sided | ◯ | ◯ | ◯ | — | — | — | — | — | 800 | 10 |
| Comp. Ex. 4 | Double-sided | ◯ | ◯ | ◯ | — | — | — | — | — | 800 | 10 |
| Comp. Ex. 5 | Double-sided | ◯ | ◯ | ◯ | — | — | — | — | — | 800 | 10 |
| Comp. Ex. 6 | Back-contact | ◯ | — | — | ◯ | ◯ | — | — | — | 800 | 10 |
| Comp. Ex. 7 | Back-contact | ◯ | — | — | ◯ | ◯ | — | — | — | 850 | 8 |
| Comp. Ex. 8 | Back-contact | — | — | — | ◯ | ◯ | — | — | — | 800 | 10 |
| Comp. Ex. 9 | Back-contact | — | — | — | ◯ | ◯ | — | — | — | 850 | 8 |
| Comp. Ex. 10 | Back-contact | — | — | — | — | ◯ | — | — | — | 800 | 10 |
| Comp. Ex. 11 | Back-contact | — | — | — | — | ◯ | — | — | — | 850 | 8 |

[Evaluation]

Evaluation of the photovoltaic cell elements was carried out with a combination of artificial sunlight (WXS-155S-10, trade name, manufactured by Wacom Electric Co., Ltd.) and a current-voltage (I-V) analyzer (I-V CURVE TRACER MP-160, trade name, manufactured by EKO Instruments Co., Ltd.).

Jsc (short circuit current), Voc (open-circuit voltage), FF (fill factor), and Eff (conversion efficiency), which indicate photovoltaic performances of a photovoltaic cell, were obtained by measurements according to JIS-C-8912, JIS-C-8913 and JIS-C-8914. The measured values of photovoltaic cell elements with a double-surface electrode structure were reduced to relative values, based on the measure values for Comparative Example 1 (photovoltaic cell element C1) that are defined as 100.0. The results are shown in Table 2. In Comparative Example 2, evaluation was not possible to carry out due to increased resistivity of the electrode caused by oxidation of copper particles.

Further, a cross-section of the light-receiving surface electrodes, formed by sintering the paste composition for an electrode, was observed with a scanning electron microscope (MINISCOPE TM-1000, trade name, manufactured by Hitachi, Ltd.) with an acceleration voltage of 15 kV, and the existence or nonexistence of a Cu—Sn alloy phase and an Sn—P—O glass phase in the electrode, and the location of the Sn—P—O glass phase. The results are shown in Table 2.

TABLE 2

| | Photovoltaic performances as photovoltaic cell | | | | | | |
|---|---|---|---|---|---|---|---|
| | Jsc | | | | Observation of electrode cross-section | | |
| | (relative | Voc | F.F. | Eff | Cu—Sn | | |
| | value) short | (relative value) | (relative | (relative value) | alloy phase | Sn—P—O glass phase | |
| | circuit | open-circuit | value) | conversion | Existence or | Existence or | |
| | current | voltage | fill factor | efficiency | Nonexistence | Nonexistence | Formed location |
| Example 1 | 99.3 | 100.2 | 99.9 | 101.1 | Existent | Existent | Between Cu—Sn alloy phase/Si substrate |
| Example 2 | 100.2 | 100.2 | 100.0 | 100.0 | Existent | Existent | Between Cu—Sn alloy phase/Si substrate |
| Example 3 | 99.1 | 99.5 | 98.9 | 99.0 | Existent | Existent | Between Cu—Sn alloy phase/Si substrate |
| Example 4 | 99.0 | 99.2 | 98.7 | 98.6 | Existent | Existent | Between Cu—Sn alloy phase/Si substrate |
| Example 5 | 101.8 | 100.2 | 101.1 | 100.6 | Existent | Existent | Between Cu—Sn alloy phase/Si substrate |
| Example 6 | 102.0 | 100.9 | 100.3 | 100.4 | Existent | Existent | Between Cu—Sn alloy phase/Si substrate |
| Example 7 | 102.1 | 100.3 | 100.4 | 101.6 | Existent | Existent | Between Cu—Sn alloy phase/Si substrate |
| Example 8 | 100.1 | 99.5 | 99.2 | 100.0 | Existent | Existent | Between Cu—Sn alloy phase/Si substrate |
| Example 9 | 100.8 | 100.9 | 100.2 | 101.1 | Existent | Existent | Between Cu—Sn alloy phase/Si substrate |
| Example 10 | 99.8 | 99.2 | 99.5 | 98.6 | Existent | Existent | Between Cu—Sn alloy phase/Si substrate |
| Example 11 | 101.3 | 101.9 | 100.9 | 100.9 | Existent | Existent | Between Cu—Sn alloy phase/Si substrate |
| Example 12 | 101.5 | 102.3 | 101.4 | 101.5 | Existent | Existent | Between Cu—Sn alloy phase/Si substrate |
| Example 13 | 100.8 | 99.8 | 99.2 | 100.2 | Existent | Existent | Between Cu—Sn alloy phase/Si substrate |
| Example 14 | 99.6 | 99.2 | 99.1 | 98.7 | Existent | Existent | Between Cu—Sn alloy phase/Si substrate |
| Example 15 | 100.2 | 100.0 | 100.1 | 99.8 | Existent | Existent | Between Cu—Sn alloy phase/Si substrate |
| Example 16 | 100.3 | 99.8 | 99.6 | 100.1 | Existent | Existent | Between Cu—Sn alloy phase/Si substrate |
| Example 17 | 99.8 | 99.6 | 99.2 | 99.3 | Existent | Existent | Between Cu—Sn alloy phase/Si substrate |
| Example 18 | 99.3 | 98.5 | 98.8 | 98.2 | Existent | Existent | Between Cu—Sn alloy phase/Si substrate |
| Example 19 | 100.3 | 100.2 | 99.8 | 99.3 | Existent | Existent | Between Cu—Sn alloy phase/Si substrate |
| Example 20 | 100.1 | 99.3 | 99.4 | 99.7 | Existent | Existent | Between Cu—Sn alloy phase/Si substrate |
| Example 21 | 99.2 | 98.6 | 98.5 | 99.3 | Existent | Existent | Between Cu—Sn alloy phase/Si substrate |
| Example 22 | 101.8 | 101.2 | 100.7 | 100.4 | Existent | Existent | Between Cu—Sn alloy phase/Si substrate |
| Example 23 | 100.8 | 100.2 | 100.3 | 100.2 | Existent | Existent | Between Cu—Sn alloy phase/Si substrate |
| Example 24 | 99.8 | 99.4 | 99.4 | 99.2 | Existent | Existent | Between Cu—Sn alloy phase/Si substrate |
| Example 25 | 100.2 | 100.0 | 99.9 | 100.4 | Existent | Existent | Between Cu—Sn alloy phase/Si substrate |
| Example 26 | 101.3 | 100.9 | 100.8 | 100.5 | Existent | Existent | Between Cu—Sn alloy phase/Si substrate |
| Comp. Ex. 1 | 100.0 | 100.0 | 100.0 | 100.0 | — | — | — |
| Comp. Ex. 2 | — | — | — | — | Not existent | Not existent | — |
| Comp. Ex. 3 | 35.8 | 42.2 | 32.2 | 11.0 | Not existent | Not existent | — |
| Comp. Ex. 4 | 45.8 | 43.5 | 30.1 | 29.7 | Not existent | Not existent | — |

As is seen from Table 2, Comparative Examples 3 and Comparative Example 4 exhibited inferior photovoltaic performances as compared to Comparative Example 1.

This is considered that Comparative Example 3, in which the phosphorus content of the copper alloy particles was 6 mass % but tin was not included, caused interdiffusion of a silicon substrate and copper during sintering, thereby deteriorating the pn-junction characteristic in the substrate. In Comparative Example 5, in which copper alloy particles containing tin but not containing phosphorus were used, it is considered that the alloy particles were oxidized during sintering, thereby increasing resistance of the electrode without forming a Cu—Sn alloy phase.

On the other hand, photovoltaic performances of the photovoltaic cell elements of Examples 1 to 26 were substantially equal to the values as measured in Comparative Example 1. In particular, the photovoltaic cell elements 24 to 26, although the paste compositions for an electrode were sintered at a relatively low temperature (650° C.), exhibited high photovoltaic performances. The results of observation of the structure showed that a Cu—Sn alloy phase and an Sn—P—O glass phase were present in the light-receiving surface electrodes, and that the Sn—P—O glass phase was formed between the Cu—Sn alloy phase and the silicon substrate.

Next, the measured values for the back-contact type photovoltaic cell elements, having a structure of FIG. 5, were reduced to relative values based on the values measured in Comparative Example 5, which were defined as 100.0. The results are shown in Table 3. The results of observation of a cross-section of the light-receiving surface electrode are also shown in Table 3.

TABLE 3

| | Photovoltaic performances as photovoltaic cell | | | | | | |
|---|---|---|---|---|---|---|---|
| | Jsc | Voc | | Eff | Observation of electrode cross-section | | |
| | (relative | (relative | | (relative | Cu—Sn | | |
| | value) | value) | F.F. | value) | alloy phase | Sn—P—O glass phase | |
| | short circuit | open-circuit | (relative value) | conversion | Existence or | Existence or | |
| | current | voltage | fill factor | efficiency | Nonexistence | Nonexistence | Formed location |
| Example 27 | 100.1 | 99.9 | 99.8 | 100.3 | Existent | Existent | Between Cu—Sn alloy phase/Si substrate |
| Example 28 | 101.1 | 100.0 | 100.2 | 100.1 | Existent | Existent | Between Cu—Sn alloy phase/Si substrate |
| Example 29 | 101.3 | 100.3 | 100.9 | 100.5 | Existent | Existent | Between Cu—Sn alloy phase/Si substrate |
| Comp. Ex. 5 | 100.0 | 100.0 | 100.0 | 100.0 | — | — | Between Cu—Sn alloy phase/Si substrate |

As is seen from Table 3, photovoltaic performances of the photovoltaic cell elements of Examples 27 to 29 were substantially equal to that of the photovoltaic cell element of Comparative Example 5. The results of observation of the structure showed that a Cu—Sn alloy phase and an Sn—P—O glass phase were present in the light-receiving surface electrodes, and that the Sn—P—O glass phase was formed between the Cu—Sn alloy phase and the silicon substrate.

Next, the measured values for the back-contact type photovoltaic cell elements, having a structure of FIG. 6, were reduced to relative values based on the values measured in Comparative Example 6, which were defined as 100.0. The results are shown in Table 4. The results of observation of a cross-section of the light-receiving surface electrode are also shown in Table 4.

TABLE 4

| | Photovoltaic performances as photovoltaic cell | | | | Observation of electrode cross-section | | |
|---|---|---|---|---|---|---|---|
| | Jsc | Voc | F.F. | Eff | Cu—Sn | | |
| | (relative value) | (relative value) | (relative | (relative value) | alloy phase | Sn—P—O glass phase | |
| | short circuit | open-circuit | value) | conversion | Existence or | Existence or | |
| | current | voltage | fill factor | efficiency | Nonexistence | Nonexistence | Formed location |
| Example | 99.6 | 99.9 | 99.4 | 99.5 | Existent | Existent | Between Cu—Sn alloy phase/Si substrate |
| 30 | | | | | | | |
| Example | 100.1 | 100.2 | 100.0 | 100.2 | Existent | Existent | Between Cu—Sn alloy phase/Si substrate |
| 31 | | | | | | | |
| Example | 100.2 | 99.8 | 99.5 | 99.7 | Existent | Existent | Between Cu—Sn alloy phase/Si substrate |
| 32 | | | | | | | |
| Comp. | 100.0 | 100.0 | 100.0 | 100.0 | — | — | Between Cu—Sn alloy phase/Si substrate |
| Ex. 9 | | | | | | | |

As is seen from Table 4, the photovoltaic cell elements of Examples 30 to 32 exhibited photovoltaic performances that were substantially equal to that of Comparative Example 6. Further, the results of observation of the structure showed that a Cu—Sn alloy phase and an Sn—P—O glass phase were present in the back surface electrode formed with the paste composition for an electrode, and that the Sn—P—O glass phase was formed between the Cu—Sn alloy phase and the silicon substrate.

Next, the measured values for the back-contact type photovoltaic cell elements, having a structure of FIG. 7, were reduced to relative values based on the values measured in Comparative Example 7, which were defined as 100.0. The results are shown in Table 5. The results of observation of a cross-section of the light-receiving surface electrode are also shown in Table 5.

TABLE 5

| | Photovoltaic performances as photovoltaic cell | | | | Observation of electrode cross-section | | |
|---|---|---|---|---|---|---|---|
| | Jsc | Voc | F.F. | Eff | Cu—Sn | | |
| | (relative value) | (relative value) | (relative | (relative value) | alloy phase | Sn—P—O glass phase | |
| | short circuit | open-circuit | value) | conversion | Existence or | Existence or | |
| | current | voltage | fill factor | efficiency | Nonexistence | Nonexistence | Formed location |
| Example | 99.1 | 99.4 | 99.6 | 99.5 | Existent | Existent | Between Cu—Sn alloy phase/Si substrate |
| 30 | | | | | | | |
| Example | 99.5 | 99.6 | 99.7 | 99.3 | Existent | Existent | Between Cu—Sn alloy phase/Si substrate |
| 31 | | | | | | | |
| Example | 100.1 | 100.0 | 100.0 | 99.9 | Existent | Existent | Between Cu—Sn alloy phase/Si substrate |
| 32 | | | | | | | |
| Comp. | 100.0 | 100.0 | 100.0 | 100.0 | — | — | Between Cu—Sn alloy phase/Si substrate |
| Ex. 7 | | | | | | | |

As is seen from Table 5, the photovoltaic cell elements of Examples 33 to 35 exhibited photovoltaic performances that were substantially equal to that of Comparative Example 7. Further, the results of observation of the structure showed that a Cu—Sn alloy phase and an Sn—P—O glass phase were present in the back surface electrode formed with the paste composition for an electrode, and that the Sn—P—O glass phase was formed between the Cu—Sn alloy phase and the silicon substrate.

The disclosure of Japanese Patent Application No. 2011-090519 is herein incorporated by reference by reference. All publications, patent applications, and technical standards mentioned in this specification are herein incorporated by reference to the same extent as if each individual publication, patent application, or technical standard was specifically and individually indicated to be incorporated by reference.

What is claimed is:

1. A paste composition for an electrode, the paste composition comprising phosphorus-tin-containing copper alloy particles, glass particles, a solvent and a resin.

2. The paste composition for an electrode according to claim 1, wherein a content of phosphorus in the phosphorus-tin-containing copper alloy particles is from 2 mass % to 15 mass %, and a content of tin in the phosphorus-tin-containing copper alloy particles is from 5 mass % to 30 mass %.

3. The paste composition for an electrode according to claim 1, wherein the glass particles have a glass softening point of 650° C. or less and a crystallization initiation temperature of more than 650° C.

4. The paste composition for an electrode according to claim 1, wherein the phosphorus-tin-containing copper alloy particles further comprise at least one kind of metal atom selected from the group consisting of silver, manganese and cobalt.

5. The paste composition for an electrode according to claim 4, wherein a content of the metal atom in the phosphorus-tin-containing copper alloy particles is from 0.1 mass % to 10 mass %.

6. The paste composition for an electrode according to claim 1, further comprising silver particles.

7. The paste composition for an electrode according to claim 6, wherein a content of the silver particles in a total content of the phosphorus-tin-containing copper alloy particles and the silver particles, which is defined as 100 mass %, is from 0.1 mass % to 10 mass %.

8. The paste composition for an electrode according to claim 6, wherein a total content of the phosphorus-tin-containing copper alloy particles and the silver particles in the paste composition is from 70 mass % to 94 mass %; a content of the glass particles in the paste composition is from 0.1 mass % to 10 mass %; and a total content of the solvent and the resin in the paste composition is from 3 mass % to 29.9 mass %.

9. A photovoltaic cell element comprising an electrode, the electrode being formed by sintering the paste composition for an electrode according to claim 1 after it has been applied onto a silicon substrate.

10. The photovoltaic cell element according to claim 9, wherein the electrode comprises a Cu—Sn alloy phase and an Sn—P—O glass phase.

11. The photovoltaic cell element according to claim 10, wherein the Sn—P—O glass phase is positioned between the Cu—Sn alloy phase and the silicon substrate.

12. A photovoltaic cell comprising the photovoltaic cell element according to claim 9, and a tab wire positioned on the electrode of the photovoltaic cell element.
